(19) United States
(12) Patent Application Publication
(10) Pub. No.: US 2025/0318380 A1
(43) Pub. Date: Oct. 9, 2025

(54) FINGERPRINT SENSOR AND DISPLAY DEVICE INCLUDING THE SAME

(71) Applicant: Samsung Display Co., Ltd., Yongin-Si, Gyeonggi-Do (KR)

(72) Inventors: Byung Han YOO, Yongin-si (KR); Gun Hee KIM, Yongin-si (KR); Hyang A PARK, Yongin-si (KR); Kwang Soo BAE, Yongin-si (KR); Bo Kwang SONG, Yongin-si (KR); Soo Yeong HONG, Yongin-si (KR)

(21) Appl. No.: 19/052,299

(22) Filed: Feb. 13, 2025

(30) Foreign Application Priority Data
Apr. 5, 2024 (KR) 10-2024-0046791

(51) Int. Cl. H10K 59/131; G06V 40/13; H10K 39/34; H10K 59/122

(52) U.S. Cl. CPC H10K 59/131; G06V 40/1318; H10K 39/34; H10K 59/122

(57) ABSTRACT

A fingerprint sensor and a display device including the same are provided. The fingerprint sensor comprises a reset voltage line disposed in a first source metal layer on a substrate, a voltage connection electrode disposed in a second source metal layer on the first source metal layer and connected to the reset voltage line, a via layer disposed on the second source metal layer and including a via contact hole which exposes a portion of the second source metal layer, a light-receiving element including a sensor electrode which is disposed on the via layer and connected to the voltage connection electrode, and a common electrode which is disposed on the sensor electrode and in the via contact hole, and a cathode connection electrode disposed in the second source metal layer, and having a side directly contacting a side of the common electrode in the via contact hole.

### CROSS-REFERENCE TO RELATED APPLICATION

This application claims priority from Korean Patent Application No. 10-2024-0046791 filed on Apr. 5, 2024, in the Korean Intellectual Property Office, and all the benefits accruing therefrom under 35 U.S.C. 119, the contents of which in its entirety are herein incorporated by reference.

### BACKGROUND

### 1. Field

The present disclosure relates to a fingerprint sensor and a display device including the same.

### 2. Description of the Related Art

With the advancement of the information society, the demand for display devices for

displaying images has increased in various forms. For example, display devices are being applied to various electronic devices such as smartphones, digital cameras, laptop computers, navigation devices, and smart televisions (TVs). Display devices can display images without backlight units to illuminate display panels by including light-emitting elements that emit light on their own.

Display devices may include display panels for displaying images, light sensors for detecting light, fingerprint sensors for detecting human fingerprints, and the like. As display devices are applied to various electronic devices, there is a demand for display devices with a variety of designs. For example, by removing separate sensor devices such as light sensors or fingerprint sensors from display devices, the display areas for displaying images can be expanded.

### SUMMARY

Aspects of the present disclosure provide a fingerprint sensor and a display device including the same, which can minimize leakage current in fingerprint sensors, even within a high-resolution structure with pixels and the fingerprint sensors densely integrated therein and can improve the sensitivity of the fingerprint sensors.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a fingerprint sensor comprises a reset voltage line disposed in a first source metal layer on a substrate, a voltage connection electrode disposed in a second source metal layer on the first source metal layer and connected to the reset voltage line, a via layer disposed on the second source metal layer and including a via contact hole which exposes a portion of the second source metal layer, a light-receiving element including a sensor electrode which is disposed on the via layer and connected to the voltage connection electrode and a common electrode which is disposed on the sensor electrode and in the via contact hole, and a cathode connection electrode disposed in the second source metal layer and having a side directly contacting a side of the common electrode in the via contact hole.

In an embodiment, the cathode connection electrode includes a first layer which is disposed on the first source metal layer and electrically connected to a first electrode of the second sensor transistor, a second layer which is disposed on the first layer, and a third layer, which is disposed on the second layer.

In an embodiment, a side of the second layer of the cathode connection electrode is inwardly recessed from sides of the first and third layers of the cathode connection electrode and directly contact the side of the common electrode.

In an embodiment, the third layer of the cathode connection electrode includes a tip protruding from a side of the second layer of the cathode connection electrode, and the common electrode is disconnected around the tip of the third layer of the cathode connection electrode.

In an embodiment, the fingerprint sensor further comprises a low-potential line disposed in the first source metal layer and supplying a low-potential voltage, a read-out line supplying a sensing signal, a first sensor transistor controlling a sensing current based on a voltage of the cathode connection electrode, a second sensor transistor electrically connecting the cathode connection electrode and the low-potential line based on a reset signal, and a third sensor transistor electrically connecting the read-out line and the first sensor transistor.

In an embodiment, a semiconductor region of the first sensor transistor is disposed in a first active layer on the substrate and includes a silicon (Si)-based material, and a semiconductor region of the second sensor transistor is disposed in a second active layer on the first active layer and includes an oxide-based material.

According to an aspect of the present disclosure, a fingerprint sensor comprises a first sensor transistor including a semiconductor region disposed in a first active layer on a substrate, a second sensor transistor including a semiconductor region disposed in a second active layer on the first active layer, a reset voltage line disposed in a first source metal layer on the second active layer and connected to a first electrode of the second sensor transistor, a sensor node electrode disposed in a second source metal layer on the first source metal layer and electrically connected to a second electrode of the second sensor transistor, a via layer disposed on the second source metal layer and including a via contact hole which exposes a portion of the second source metal layer, a light-receiving element disposed on the via layer and including a sensor electrode which is connected to the sensor node electrode and a common electrode which is disposed on the sensor electrode and in the via contact hole, and a cathode connection electrode disposed in the second source metal layer and having a side directly contact a side of the common electrode in the via contact hole.

In an embodiment, the cathode connection electrode includes a first layer which is disposed on the first source metal layer and electrically connected to a first electrode of the second sensor transistor, a second layer which is disposed on the first layer, and a third layer, which is disposed on the second layer.

In an embodiment, a side of the second layer of the cathode connection electrode is inwardly recessed from sides of the first and third layers of the cathode connection electrode and directly contact the side of the common electrode.

In an embodiment, the third layer of the cathode connection electrode includes a tip protruding from a side of the second layer of the cathode connection electrode and the common electrode is disconnected around the tip of the third layer of the cathode connection electrode.

In an embodiment, the fingerprint sensor further comprises a low-potential line disposed in the first source metal layer and supplying a low-potential voltage, and a connection electrode disposed in the first source metal layer and electrically connecting a second electrode of the second sensor transistor and the sensor node electrode.

In an embodiment, the fingerprint sensor further comprises a read-out line supplying a sensing signal, and a third sensor transistor electrically connecting the read-out line and the first sensor transistor.

According to an aspect of the present disclosure, a display device comprises a reset voltage line disposed in a first source metal layer on a substrate, a voltage connection electrode disposed in a second source metal layer on the first source metal layer, and connected to the reset voltage line, a via layer disposed on the second source metal layer and including a via contact hole which exposes a portion of the second source metal layer, a pixel-defining film disposed on the via layer and defining an emission area and a sensor area, a light-emitting element including a pixel electrode disposed in the emission area on the via layer, a light-emitting layer disposed on the pixel electrode, and a common electrode disposed on the light-emitting layer, a light-receiving element including a sensor electrode which is disposed in the sensor area on the via layer and is connected to the voltage connection electrode, a light-receiving layer which is disposed on the sensor electrode, and a common electrode which is disposed in the light-receiving layer, a separation portion disposed on the pixel-defining film and separating the common electrode of the light-emitting element and the common electrode of the light-receiving element, and a cathode connection electrode disposed in the second source metal layer and having a side directly contacting a side of the common electrode of the light-receiving element in the via contact hole.

In an embodiment, the separation portion has a closed-loop shape surrounding the sensor area, the via contact hole, and the cathode connection electrode.

In an embodiment, the display device further comprises a low-potential line disposed in the first source metal layer and supplying a low-potential voltage, a read-out line supplying a sensing signal, a first sensor transistor controlling a sensing current based on a voltage of the cathode connection electrode, a second sensor transistor electrically connecting the cathode connection electrode and the low-potential line i a reset signal, and a third sensor transistor electrically connecting the read-out line and the first sensor transistor.

In an embodiment, the common electrode of the light-emitting element is directly connected to the low-potential line, and the common electrode of the light-receiving element is electrically connected to the second sensor transistor.

In an embodiment, the display device further comprises another cathode connection electrode, wherein the via layer includes a plurality of via contact holes, which are surrounded by the separation portion, the cathode connection electrode and the another cathode connection electrode are disposed in the respective via contact holes, and the common electrode of the light-receiving element directly contacts each of the cathode connection electrode and the another cathode connection electrode.

In an embodiment, the cathode connection electrode includes a first layer which is disposed on the first source metal layer and electrically connected to a first electrode of the second sensor transistor, a second layer which is disposed on the first layer, and a third layer, which is disposed on the second layer.

In an embodiment, a side of the second layer of the cathode connection electrode is inwardly recessed from sides of the first and third layers of the cathode connection electrode and directly contact the side of the common electrode.

In an embodiment, the third layer of the cathode connection electrode includes a tip protruding from a side of the second layer of the cathode connection electrode, and the common electrode is disconnected around the tip of the third layer of the cathode connection electrode.

According to some embodiments of the present disclosure, an electronic device, comprises a display device configured to provide an image, a display device configured to provide an image, a processor configured to provide an image data signal to the display device, a memory configured to store a data information for operation, and a power module configured to generate power, wherein the display device comprises, a reset voltage line disposed in a first source metal layer on a substrate, a voltage connection electrode disposed in a second source metal layer on the first source metal layer, and connected to the reset voltage line, a via layer disposed on the second source metal layer and including a via contact hole which exposes a portion of the second source metal layer, a pixel-defining film disposed on the via layer and defining an emission area and a sensor area, a light-emitting element including a pixel electrode disposed in the emission area on the via layer, a light-emitting layer disposed on the pixel electrode, and a common electrode disposed on the light-emitting layer, a light-receiving element including a sensor electrode which is disposed in the sensor area on the via layer and is connected to the voltage connection electrode, a light-receiving layer which is disposed on the sensor electrode, and a common electrode which is disposed in the light-receiving layer, a separation portion disposed on the pixel-defining film and separating the common electrode of the light-emitting element and the common electrode of the light-receiving element, and a cathode connection electrode disposed in the second source metal layer and having a side directly contacting a side of the common electrode of the light-receiving element in the via contact hole.

According to the aforementioned and other embodiments of the present disclosure, by separating the common electrode of pixels and the common electrodes of fingerprint sensors through separation portions arranged on a pixel-defining film, leakage current within the fingerprint sensors can be minimized, even within a high-resolution structure with the pixels and fingerprint sensors densely integrated therein, and the sensitivity of the fingerprint sensors can be improved.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to an embodiment of the present disclosure;

FIG. 2 is a cross-sectional view illustrating the display device according to an embodiment of the present disclosure;

FIG. 3 is a plan view illustrating a display unit of the display device according to an embodiment of the present disclosure;

FIG. 4 is a block diagram illustrating a display panel and a display driving unit of the display device according to an embodiment of the present disclosure;

FIG. 5 is a plan view illustrating emission areas, a sensor area, and a separation portion of the display device according to an embodiment of the present disclosure;

FIG. 6 is a circuit diagram illustrating a pixel of the display device according to an embodiment of the present disclosure;

FIG. 7 is a cross-sectional view illustrating a pixel of the display device according to an embodiment of the present disclosure;

FIG. 8 is a circuit diagram illustrating a fingerprint sensor of the display device according to an embodiment of the present disclosure;

FIG. 9 is a cross-sectional view taken along line I-I′ of FIG. 5;

FIG. 10 is an enlarged circuit diagram of an area A1 of FIG. 9;

FIG. 11 is a circuit diagram illustrating a fingerprint sensor of a display device according to another embodiment of the present disclosure;

FIG. 12 is another cross-sectional view taken along line I-I′ of FIG. 5;

FIG. 13 is a plan view illustrating emission areas, a sensor area, and a separation portion of a display device according to another embodiment of the present disclosure;

FIG. 14 is a cross-sectional view taken along line II-II' of FIG. 13;

FIG. 15 is a plan view illustrating emission areas, a sensor area, and a separation portion of a display device according to another embodiment of the present disclosure;

FIG. 16 is a plan view illustrating emission areas, a sensor area, and a separation portion of a display device according to another embodiment of the present disclosure; and

FIG. 17 is a plan view illustrating emission areas, a sensor area, and a separation portion of a display device according to another embodiment of the present disclosure.

FIG. 18 is a block diagram of an electronic device according to one embodiment of the present disclosure.

FIG. 19 is a schematic diagram of an electronic device according to various embodiments of the present disclosure.

### DETAILED DESCRIPTION

The present inventive concept will now be described more fully hereinafter with reference to the accompanying drawings, in which preferred embodiments of the inventive concept are shown. This inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

It will also be understood that when a layer is referred to as being “on” another layer or substrate, it can be directly on the other layer or substrate, or intervening layers may also be present. The same reference numbers indicate the same components throughout the specification. It will be understood that, although the terms “first,” “second,” etc. may be used

herein to describe various elements, these elements should not be limited by these terms. These terms are only used to distinguish one element from another element. For instance, a first element discussed below could be termed a second element without departing from the teachings of the present inventive concept. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, embodiments will be described with reference to the accompanying drawings.

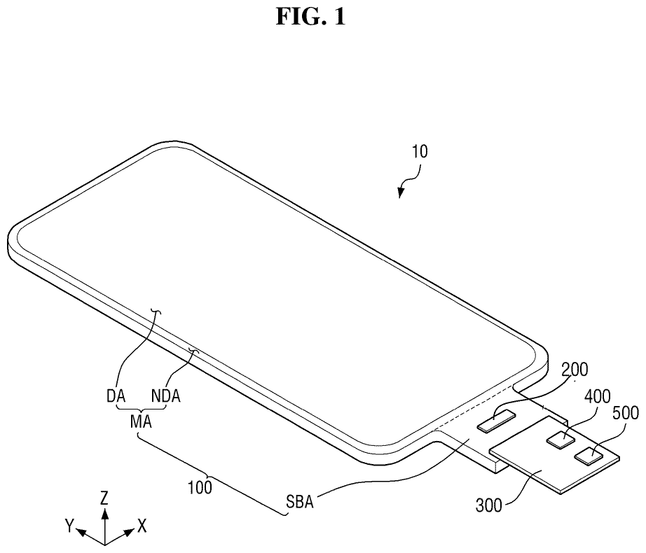

FIG. 1 is a perspective view illustrating a display device according to an embodiment of the present disclosure.

Referring to FIG. 1, a display device 10 may be applicable to a portable electronic device such as a mobile phone, a smartphone, a tablet personal computer (PC), a mobile communication terminal, an electronic notepad, an electronic book (e-book), a portable multimedia player (PMP), a navigation device, or an ultra-mobile PC (UMPC). For example, the display device 10 may be used as the display unit of a television (TV), a laptop computer, a monitor, a billboard, or an Internet-of-Things (IoT) device. In another example, the display device 10 may be applicable to a wearable device such as a smartwatch, a watchphone, a glasses display, or a head-mounted display (HMD).

The display device 10 may have a rectangular shape in a plan view. For example, the display device 10 may have a rectangular shape in a plan view, with short sides in an X-axis direction and long sides in a Y-axis direction. The corners where the short sides and the long sides meet may be rounded to a predetermined curvature or may be right-angled. However, the planar shape of the display device 10 is not particularly limited, and the display device 10 may have various other shapes such as another polygonal shape, a circular shape, or an elliptical shape in a plan view.

The display device 10 may include a display panel 100, a display driver 200, a circuit board 300, a touch driver 400, and a power supply unit 500.

The display panel 100 may include a main area MA and a subarea SBA.

The main area MA may include a display area DA which includes pixels for displaying an image and a non-display area NDA which is disposed around the display area DA.

The display area DA may emit light through a plurality of emission areas or openings. For example, the display panel 100 may include pixel circuits including switching elements, a pixel-defining film defining the emission areas or the openings, and self-light-emitting elements.

For example, the self-light-emitting elements may include organic light-emitting diodes (OLEDs), quantum-dot light-emitting diodes (LEDs) including a quantum-dot light-emitting layer, inorganic LEDs including an inorganic semiconductor, and/or micro-LEDs, but the present disclosure is not limited thereto.

The non-display area NDA may be disposed outside of the display area DA. The non-display area NDA may be defined as an edge portion of the main area MA. The non-display area NDA may include a gate driving unit (not illustrated) providing gate signals to gate lines and fan-out lines (not illustrated) connecting the display driving unit 200 and pixels in the display area DA.

The subarea SBA may be an area extending from one side of the main area MA. The subarea SBA may include a flexible material that is bendable, foldable, or rollable. For example, in a case where the subarea SBA is bendable, the subarea SBA may be bent to overlap with the main area MA in a thickness direction (or a Z-axis direction). The display driving unit 200 and a pad unit which is connected to the circuit board 300 may be disposed in the subarea SBA. The subarea SBA may be optional, and the display driving unit 200 and the pad unit may be disposed in the non-display area NDA.

The display driving unit 200 may output signals and voltages for driving the display panel 100. The display driving unit 200 may provide data voltages to data lines. The display driving unit 200 may provide a power supply voltage to each power supply line and may provide a gate control signal to the gate driving unit. The display driving unit 200 may receive a sensing signal through each read-out line. The display driving unit 200 may be formed as an integrated circuit (IC) and may be mounted on the display panel 100 in a chip-on-glass (COG) or chip-on-plastic (COP) manner, or via ultrasonic bonding. For example, the display driving unit 200 may be disposed in the subarea SBA and may overlap with the main area MA in the thickness direction (or the Z-axis direction) when the subarea SBA is bent. In another example, the display driving unit 200 may be mounted on the circuit board 300.

The circuit board 300 may be attached to the pad unit of the display panel 100 via an anisotropic conductive film (ACF). Lead lines of the circuit board 300 may be electrically connected to the pad unit of the display panel 100. The circuit board 300 may be a printed circuit board (PCB), a flexible PCB (FPCB), or a flexible film such as a chip-on-film (COF).

The touch driving unit 400 may be mounted on the circuit board 300. The touch driving unit 400 may be electrically connected to a touch sensing unit of the display panel 100. The touch driving unit 400 may provide a touch driving signal to a plurality of touch electrodes of the touch sensing unit and may sense capacitance variations between the touch electrodes. For example, the touch driving signal may be a pulse signal having a predetermined frequency. The touch driving unit 400 may calculate the presence and coordinates of input based on capacitance variations between the touch electrodes. The touch driving unit 400 may be formed as an integrated circuit (IC).

The power supply unit 500 may be disposed on the circuit board 300 and may provide a power supply voltage to each of the display driving unit 200 and the display panel 100. The power supply unit 500 may generate a driving voltage and provide the driving voltage to each driving voltage line and may generate a common voltage and provide the common voltage to a common electrode that light-emitting elements of pixels have in common. For example, the driving voltage may be a high-potential voltage for driving the light-emitting elements and the common voltage may be a low-potential voltage for driving the light-emitting elements. The power supply unit 500 may generate an initialization voltage and provide the initialization voltage to each initialization line, may generate a reference voltage and provide the reference voltage to each reference voltage line, may generate a bias voltage and provide the bias voltage to each bias voltage line, and may generate a reset voltage and provide the reset voltage to each reset voltage line.

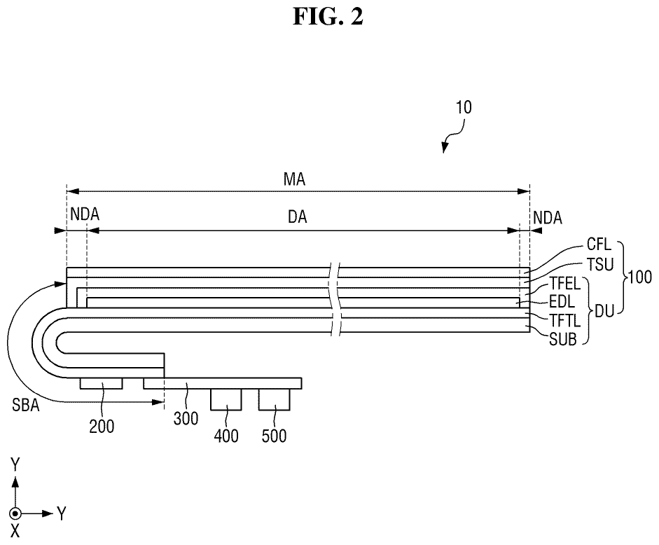

FIG. 2 is a cross-sectional view illustrating the display device according to an embodiment of the present disclosure.

Referring to FIG. 2, the display panel 100 may include a display unit DU, a touch sensing unit TSU, and a color filter layer CFL. The display unit DU may include a substrate SUB, a transistor layer TFTL, a light-emitting element layer EDL, and an encapsulation layer TFEL.

The substrate SUB may be a base substrate or member. The substrate SUB may be a flexible substrate that is bendable, foldable, or rollable. For example, the substrate SUB may include a polymer resin such as polyimide (PI), but the present disclosure is not limited thereto. In another example, the substrate SUB may include a glass material or a metal material.

The transistor layer TFTL may be disposed on the substrate SUB. The transistor layer TFTL may include a plurality of transistors that form pixels and fingerprint sensors. The transistor layer TFTL may further include gate lines, data lines, power supply lines, read-out lines, gate control lines, and fan-out lines connecting the display driving unit 200 and the data lines, and lead lines connecting the display driving unit 200 and the pad unit. The transistors may include semiconductor regions, source electrodes, drain electrodes, and gate electrodes. For example, in a case where the gate driving unit is formed on one side of the non-display area NDA of the display panel 100, the gate driving unit may include transistors.

The transistor layer TFTL may be disposed in the display area DA, the non-display area NDA, and the subarea SBA. The transistors, the gate lines, the data lines, the power supply lines, and the read-out lines of the transistor layer TFTL may be disposed in the display area DA. The gate control lines and the fan-out lines of the transistor layer TFTL may be disposed in the non-display area NDA. The lead lines of the transistor layer TFTL may be disposed in the subarea SBA.

The light-emitting element layer EDL may be disposed on the transistor layer TFTL. The light-emitting element layer EDL may include the light-emitting elements of the pixels, light-receiving elements of the fingerprint sensors, and a pixel-defining film defining both the pixels and the fingerprint sensors. In the light-emitting elements, pixel electrodes, light-emitting layers, and a common electrode may be sequentially stacked to emit light, and in the light-receiving elements, sensor electrodes, light-receiving layers, and a common electrode may be sequentially stacked to receive light. The light-emitting elements and light-receiving elements of the light-emitting element layer EDL may be disposed in the display area DA.

For example, the light-emitting layers may be organic light-emitting layers each including an organic material. The light-emitting layers may include hole transport layers, organic light-emitting layers, and electron transport layers. As the pixel electrodes receive a predetermined voltage through the transistors of the transistor layer TFTL and the common electrodes receive a cathode voltage, holes may move to the organic light-emitting layers through the hole transport layers, electrons may move to the organic light-emitting layers through the electron transport layers, and the holes and the electrons may combine together in the organic light-emitting layers, thereby emitting light. For example, the pixel electrodes and the common electrodes may be anodes and cathodes, respectively, but the present disclosure is not limited thereto.

In another example, the light-emitting elements may be quantum-dot light-emitting diodes (LEDs) including quantum-dot light-emitting layers, inorganic LEDs including an inorganic semiconductor, or micro-LEDs.

The light-receiving elements may receive light and convert its optical energy into electrical signals. When a user's finger contacts the display panel 100, light emitted from the light-emitting elements may be reflected by the finger, and the light-receiving elements may receive the reflected light. Sensing signals from light-receiving elements receiving light reflected by the ridges on the finger of a user may differ from sensing signals from light-receiving elements receiving light reflected by the valleys on the finger. A main processor (not illustrated) may distinguish such differences in sensing signals to generate sensing data and may determine whether the display panel 100 is in contact with the ridges or valleys of the finger. Consequently, the display device 10 can recognize the pattern of the user's fingerprint based on the sensing data. For example, the light-receiving elements may be organic photodiodes, but the present disclosure is not limited thereto.

The encapsulation layer TFEL may cover the top surface and sides of the light-emitting element layer EDL and may protect the light-emitting element layer EDL. The encapsulation layer TFEL may include at least one inorganic film and at least one organic film for encapsulating the light-emitting element layer EDL.

The touch sensing unit TSU may be disposed on the encapsulation layer TFEL. The touch sensing unit TSU may include a plurality of touch electrodes for detecting touch input from the user in a capacitive manner and touch lines for connecting the touch electrodes and the touch driving unit 400. The touch electrodes of the touch sensing unit TSU may be disposed in a touch sensor area overlapping with the display area DA. The touch lines of the touch sensing unit TSU may be disposed in a touch peripheral area overlapping with the non-display area NDA. For example, the touch sensing unit TSU may sense touch input from the user in a mutual capacitance manner or in a self-capacitance manner.

In another example, the touch sensing unit TSU may be disposed on a separate substrate which is disposed on the display unit DU. In this example, the separate substrate may be a base member encapsulating the display unit DU.

The color filter layer CFL may be disposed on the touch sensing unit TSU. The color filter layer CFL may include the color filters which is disposed in areas corresponding to their respective emission areas. The color filters may selectively transmit light of a particular wavelength therethrough and may block or absorb light of other wavelengths. The color filters may reduce reflected light of external light by absorbing some of the external light. Accordingly, the color filters can prevent color distortion that may be caused by the external light.

As the color filter layer CFL is disposed directly on the touch sensing unit TSU, the display device 10 may not need a separate substrate for the color filter layer CFL. Thus, the thickness of the display device 10 can be reduced.

The subarea SBA of the display panel 100 may extend from a side of the main area MA. The subarea SBA may include a flexible material that is bendable, foldable, or rollable. For example, when the subarea SBA is bent, the subarea SBA may overlap with the main area MA in the thickness direction (or the Z-axis direction). The subarea SBA may include a display driving unit 200 and a pad unit, which is electrically connected to a circuit board 300.

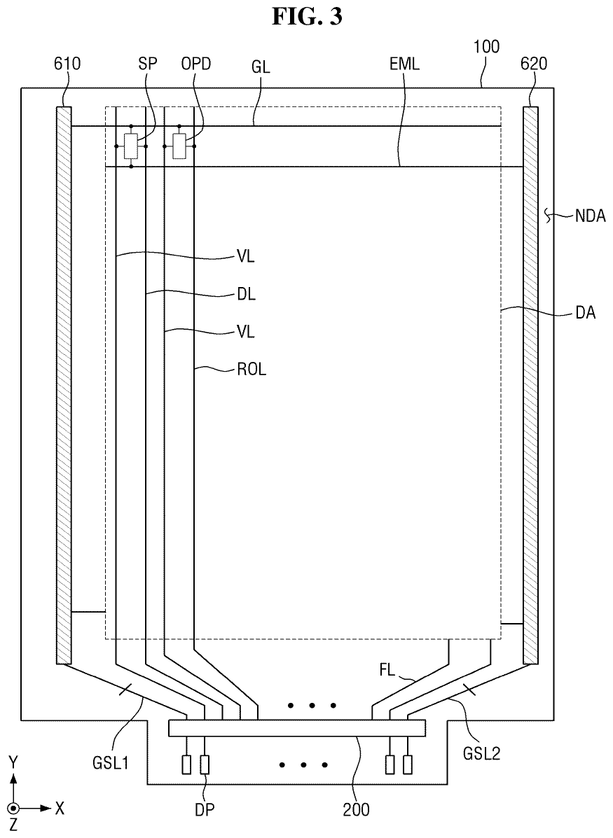

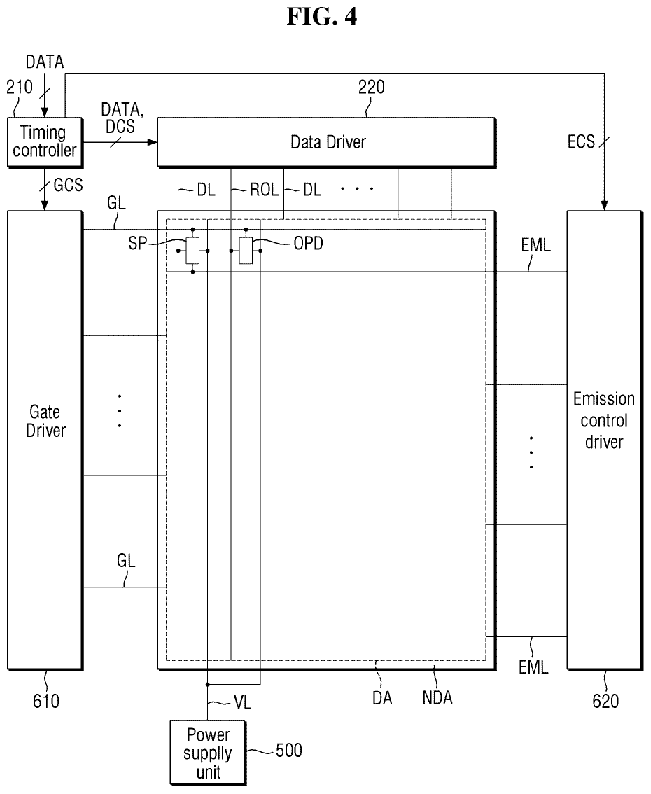

FIG. 3 is a plan view illustrating the display unit of the display device according to an embodiment of the present disclosure, and FIG. 4 is a block diagram illustrating the display panel and the display driving unit of the display device according to an embodiment of the present disclosure.

Referring to FIGS. 3 and 4, the display panel 100 may include the display area DA and the non-display area NDA. The display area DA may include pixels SP, fingerprint sensors OPD, power supply lines VL, data lines DL, read-out lines ROL, gate lines GL, emission control lines EML.

The pixels SP may be connected to the gate lines GL, the emission control lines EML, the data lines DL, and the power supply lines VL. Each of the pixels SP may include at least one transistor, a light-emitting element, and a capacitor.

The fingerprint sensors OPD may be connected to the gate lines GL, the power supply lines VL, and the read-out lines ROL. Each of the fingerprint sensors OPD may include at least one transistor and a light-receiving element.

The gate lines GL may extend in the X-axis direction and may be spaced apart from one another in the Y-axis direction which intersects the X-axis direction. The gate lines GL may sequentially provide gate signals to both the pixels SP and the fingerprint sensors OPD.

The emission control lines EML may extend in the X-axis direction and may be spaced apart from one another in the Y-axis direction. The emission control lines EML may sequentially provide emission signals to the pixels SP.

The data lines DL may extend in the Y-axis direction and may be spaced apart from one another in the X-axis direction. The data lines DL may provide data voltages to the pixels SP. The data voltages may determine the luminances of the pixels SP.

The power supply lines VL may extend in the Y-axis direction and may be spaced apart from one another in the X-axis direction. The power supply lines VL may provide power supply voltage to both the pixels SP and the fingerprint sensors OPD. Here, the power supply voltage may be a driving voltage, a common voltage, an initialization voltage, a reference voltage, a bias voltage, or a reset voltage. The driving voltage may be a high-potential voltage for driving the light-emitting elements of the pixels SP and the common voltage may be a low-potential voltage for driving both the light-emitting elements and the light-receiving elements.

The non-display area NDA may surround the display area DA. The non-display area NDA may include a gate driver 610, an emission control driver 620, fan-out lines FL, a first gate control line GSL1, and a second gate control line GSL2.

The fan-out lines FL may extend from the display driving unit 200 to the display area DA. The fan-out lines FL may provide data voltages received from the display driving unit 200 to the data lines DL, may provide power supply voltages received from the display driving unit 200 to the power supply lines VL, and may provide sensing signals received from the read-out lines ROL to the display driving unit 200. Accordingly, the display driving unit 200 can drive the pixels SP and the fingerprint sensors OPD.

The first gate control line GSL1 may extend from the display driving unit 200 to the gate driver 610. The first gate control line GSL1 may provide gate control signals GCS received from the display driving unit 200 to the gate driver 610.

The second gate control line GSL2 may extend from the display driving unit 200 to the emission control driver 620. The second gate control line GSL2 may provide emission control signals ECS received from the display driving unit 200 to the emission control driver 620.

The subarea SBA may extend from a side of the non-display area NDA. The display driving unit 200 and a pad unit DP may be disposed in the subarea SBA. The pad unit DP may be disposed closer than the display driving unit 200 to the edge of the subarea SBA. The pad unit DP may be electrically connected to the circuit board 300 via an anisotropic conductive film (ACF).

The display driving unit 200 may include a timing controller 210 and a data driver 220.

The timing controller 210 may receive digital video data “DATA” and timing signals from the circuit board 300. The timing controller 210 may generate data control signals DCS based on the timing signals and control the operation timing of the data driver 220, may generate the gate control signals GCS based on the timing signals and control the operation timing of the gate driver 610, and may generate the emission control signals ECS based on the timing signals and control the operation timing of the emission control driver 620. The timing controller 210 may provide the gate control signals to the gate driver 610 via the first gate control line GSL1. The timing controller 210 may provide the emission control signals ECS to the emission control driver 620 via the second gate control line GSL2. The timing controller 210 may provide the digital video data “DATA” and the data control signals DCS to the data driver 220.

The data driver 220 may convert the digital video data “DATA” into analog data voltages and may provide the analog data voltages to the data lines DL through the fan-out lines FL. The gate signals from the gate driver 610 may select pixels SP to which the data voltages are to be provided, and the selected pixels SP may receive the data voltages through the data lines DL. The data driver 220 may provide sensing signals received through the read-out lines ROL to the main processor.

The power supply unit 500 may be disposed on the circuit board 300 to supply power supply voltages to the display driving unit 200 and the display panel 100. The power supply unit 500 may generate a power supply voltage and supply the power supply voltage to the power supply lines VL, and may generate a common voltage and supply the common voltage to the common electrodes that the pixels SP and the fingerprint sensors OPD respectively have in common. The power supply unit 500 may generate an initialization voltage and supply the initialization voltage to the initialization lines, may generate a reference voltage and supply the reference voltage to the reference voltage lines, may generate a bias voltage and supply the bias voltage to the bias voltage lines, and may generate a reset voltage and supply the reset voltage to the reset voltage lines.

The gate driver 610 may be disposed in one side of the display area DA in the non-display area NDA and the emission control driver 620 may be disposed in another side of the display area DA in the non-display area NDA. However, the present disclosure is not limited to this. Alternatively, the gate driver 610 and the emission control driver 620 may both be disposed on the same side of the display area DA in the non-display area NDA.

The gate driver 610 may include a plurality of transistors, which generate gate signals based on the gate control signals GCS. The emission control driver 620 may include a plurality of transistors which generate emission signals based on the emission control signals ECS. For example, the transistors of the gate driver 610 and the transistors of the emission control driver 620 may be formed in the same layer as the transistors of each of the pixels SP. The gate driver 610 may provide the gate signals to the gate lines GL and the emission control driver 620 may provide the emission signals to the emission control lines EML.

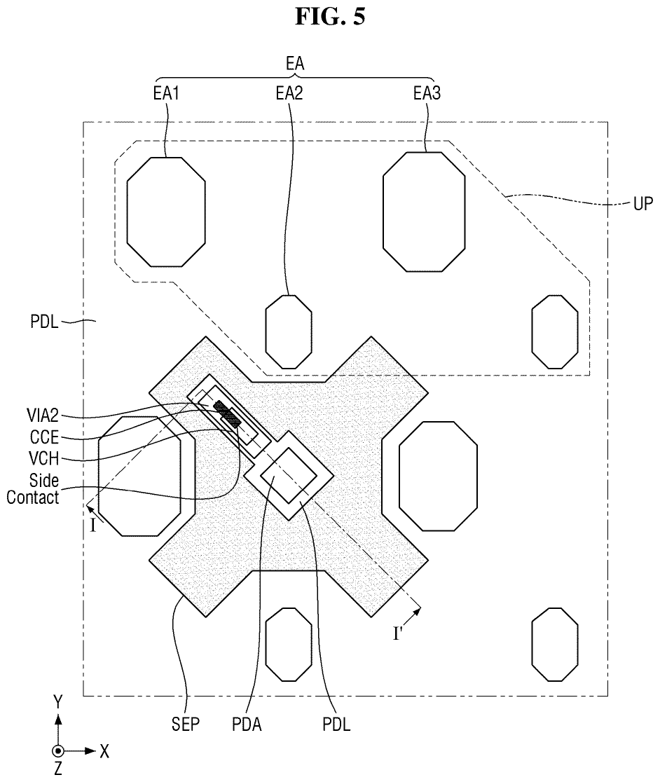

FIG. 5 is a plan view illustrating emission areas, a sensor area, and a separation portion of the display device according to an embodiment of the present disclosure.

Referring to FIG. 5, the display area DA may include emission areas EA and a sensor area PDA. The emission areas EA and the sensor area PDA may be defined by a pixel-defining film PDL. The emission areas EA may emit light emitted by the light-emitting elements. The emission areas EA may include first emission areas EA1, second emission areas EA2, and third emission areas EA3. For example, the first emission areas EA1 may emit first-color light or red light, the second emission areas EA2 may emit second-color light or green light, and the third emission areas EA3 may emit third-color light or blue light. However, the present disclosure is not limited to this example.

A single unit pixel UP may include one first emission area EA1, two second emission areas EA2, and one third emission area EA3 and may represent white gradation, but the configuration of the unit pixel UP is not limited thereto. White gradation may be represented by a combination of light emitted from one first emission area EA1, light emitted from two second emission areas EA2, and light emitted from one third emission areas EA3.

The first emission areas EA1, the second emission areas EA2, and the third emission areas EA3 may have different sizes. For example, the third emission areas EA3 may be larger than the first emission areas EA1, and the first emission areas EA1 may be larger than the second emission areas EA2. However, the present disclosure is not limited to this example. In another example, the first emission areas EA1, the second emission areas EA2, and the third emission areas EA3 may have the same size.

The sensor area PDA may be surrounded by a first emission area EA1, two second emission areas EA2, and a third emission area EA3. The sensor area PDA may be disposed adjacent to a first or third emission area EA1 or EA3 in the X-axis direction and may be disposed adjacent to a second emission area EA2 in the Y-axis direction. The sensor area PDA may be spaced apart from other sensor areas PDA with at least one emission area EA disposed therebetween. The sensor area PDA may receive light reflected by a finger.

The emission areas EA and the sensor area PDA may be spaced apart from each other with the separation portion SEP disposed therebetween. In the separation portion SEP, the common electrode of the light-emitting elements of a pixel SP and the common electrode of the light-receiving elements of a fingerprint sensor OPD is separated. The separation portion SEP may be disposed on the pixel-defining film PDL and may separate a common electrode of the pixel SP and a common electrode of the fingerprint sensor OPD that are both disposed on the front surface of the display panel 100. Consequently, the common electrode of the pixel SP and the common electrode of the fingerprint sensor OPD may be electrically insulated. As the common electrodes of the pixel SP and the fingerprint sensor OPD are separated, the display device 10 can minimize leakage current to the fingerprint sensor OPD, even within a high-resolution structure with multiple pixels SP and multiple fingerprint sensors OPD densely packed therein, and can improve the sensitivity of the fingerprint sensors OPD.

The separation portion SEP may have a closed-loop shape surrounding the sensor area PDA. The separation portion SEP may be disposed around the emission areas EA surrounding the sensor area PDA. For example, the separation portion SEP may extend in a direction diagonal to the X- and Y-axis directions to be disposed between first and second emission areas EA1 and EA2. The separation portion SEP may extend in a direction diagonal to the X-axis direction and the Y-axis direction to be disposed between the second emission area EA2 and a third emission area EA3. Thus, the separation portion SEP may separate the sensor area PDA from the emission areas EA and may be disposed between adjacent emission areas EA. Since the separation portion SEP has a relatively large width between the sensor area PDA and the emission areas EA, the separation portion SEP can secure margins for the pixel-defining film PDL in a high-resolution display device 10.

A second via layer VIA2 may be disposed below the pixel-defining film PDL. Parts of the second via layer VIA2 including areas corresponding to the emission areas EA and the sensor area PDA may be exposed through the openings in the pixel-defining film PDL. Moreover, parts of the second via layer VIA2 other than the areas corresponding to the emission areas EA and the sensor area PDA may also be exposed through the openings in the pixel-defining film PDL. The second via layer VIA2 may include via contact holes VCH. Cathode connection electrodes CCE may be disposed below the second via layer VIA2, and parts of the cathode connection electrodes CCE may be exposed through the via contact holes VCH. The sides of the cathode connection electrodes CCE may directly contact the sides of the common electrode of the fingerprint sensor OPD in the respective via contact holes VCH. Thus, the cathode connection electrodes CCE and the common electrode of the fingerprint sensor OPD can be electrically connected through side contacts. The common electrode of the light emitting element ELD and the common electrode of the fingerprint sensor OPD may be disconnected in the respective via contact holes VCH.

For example, the via contact holes VCH may be spaced apart from the sensor area PDA in the diagonal direction between the X-axis and the Y-axis direction and surrounded by second emission areas EA2, a third emission area EA3, and the sensor area PDA, but the present disclosure is not limited thereto.

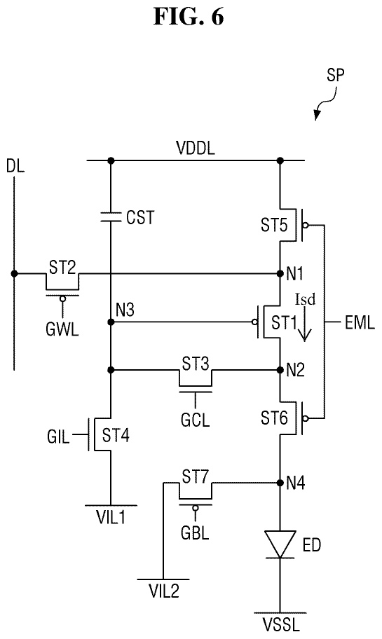

FIG. 6 is a circuit diagram illustrating a pixel of the display device of FIG. 1.

Referring to FIG. 6, a pixel SP may be connected to a first gate line GWL, a second gate line GCL, a third gate line GIL, a fourth gate line GBL, an emission control line EML, a data line DL, a driving voltage line VDDL, a first initialization voltage line VIL1, a second initialization voltage line VIL2, and a low-potential line VSSL.

The pixel SP may include a light-emitting element ED and a pixel circuit driving the light-emitting element ED. The pixel circuit may include first through seventh transistors ST1 through ST7 and one capacitor CST.

The first transistor ST1 may control a driving current to be applied to the light-emitting element ED. The first transistor ST1 may include a gate electrode, a first electrode, and a second electrode. The gate electrode of the first transistor ST1 may be connected to a third node N3, the first electrode of the first transistor ST1 may be connected to a first node N1, and the second electrode of the first transistor ST1 may be connected to a second node N2. For example, the first and second electrodes of the first transistor ST1 may be source and drain electrodes, respectively, but the present disclosure is not limited thereto.

The first transistor ST1 may control source-drain current Isd (hereinafter referred to as the driving current) based on a data voltage applied to the gate electrode of the first transistor ST1. The driving current Isd which flows through the channel of the first transistor ST1 may be proportional to the square of the difference between a voltage Vgs across the gate and source electrodes of the first transistor ST1 and a threshold voltage Vth of the first transistor ST1, i.e., Isd=k×(Vgs−Vth)² where k is a proportional coefficient determined by the structure and physical characteristics of the first transistor ST1.

The light-emitting element ED may receive the driving current Isd and may thus emit light. The amount of light emitted by the light-emitting element ED or the luminance of the light-emitting element ED may be proportional to the magnitude of the driving current Isd. The light-emitting element ED may include a first electrode, a second electrode, and a light-emitting layer disposed between the first and second electrodes. The first electrode of the light-emitting element ED may be connected to a fourth node N4. The first electrode of the light-emitting element ED may be connected to a second electrode of the sixth transistor ST6 and a first electrode of the seventh transistor ST7 through the fourth node N4. The second electrode of the light-emitting element ED may be electrically connected to a low-potential line VSSL. The second electrode of the light-emitting element ED may receive a low-potential voltage from the low-potential line VSSL. For example, the first electrode of the light-emitting element ED may be, but is not limited to, an anode or a pixel electrode, and the second electrode may be, but is not limited to, a cathode or a common electrode.

The second transistor ST2 may be turned on in response to a first gate signal from the first gate line GWL to electrically connect the data line DL and the first node N1 which is the first electrode of the first transistor ST1. As the second transistor ST2 is turned on in response to the first gate signal, the second transistor ST2 may provide a data voltage to the first node N1. A gate electrode of the second transistor ST2 may be connected to the first gate lien GWL, a first electrode of the second transistor ST2 may be connected to the data line DL, and a second electrode of the second transistor ST2 may be connected to the first node N1. The second electrode of the second transistor ST2 may be connected to the first electrode of the first transistor ST1 and a second electrode of the fifth transistor ST5 through the first node N1. For example, the first and second electrodes of the second transistor ST2 may be source and drain electrodes, respectively, but the present disclosure is not limited thereto.

The third transistor ST3 may be turned on in response to a second gate signal from the second gate line GCL to electrically connect the second node N2 which is the second electrode of the first transistor ST1 and the third node N3 which is the gate electrode of the first transistor ST1. A gate electrode of the third transistor ST3 may be connected to the second gate line GCL, a first electrode of the third transistor ST3 may be connected to the second node N2, and a second electrode of the third transistor ST3 may be connected to the third node N3. The first electrode of the third transistor ST3 may be connected to the second electrode of the first transistor ST1 and a first electrode of the sixth transistor ST6 through the second node N2. The second electrode of the third transistor ST3 may be connected to the gate electrode of the first transistor ST1, a first electrode of the fourth transistor ST4, and a first capacitor electrode of the capacitor CST through the third node N3. For example, the first and second electrodes of the third transistor ST3 may be drain and source electrodes, respectively, but the present disclosure is not limited thereto.

The fourth transistor ST4 may be turned on in response to a third gate signal from the third gate line GIL to electrically connect the third node N3 which is the gate electrode of the first transistor ST1 and the first initialization voltage line VIL1. As the fourth transistor ST4 is turned on in response to the third gate signal, the gate electrode of the first transistor ST1 may be discharged to as low as a first initialization voltage. A gate electrode of the fourth transistor ST4 may be connected to the third gate line GIL, a first electrode of the fourth transistor ST4 may be connected to the third node N3, and a second electrode of the fourth transistor ST4 may be connected to the first initialization voltage line VIL1. The first electrode of the fourth transistor ST4 may be connected to the gate electrode of the first transistor ST1, the second electrode of the third transistor ST3, and the first capacitor electrode of the capacitor CST through the third node N3. For example, the first and second electrodes of the fourth transistor ST4 may be drain and source electrodes, respectively, but the present disclosure is not limited thereto.

The fifth transistor ST5 may be turned on in response to an emission signal from the emission control line EML to electrically connect the driving voltage line VDDL and the first node N1 which is the first electrode of the first transistor ST1. A gate electrode of the fifth transistor ST5 may be connected to the emission control line EML, a first electrode of the fifth transistor ST5 may be connected to the driving voltage line VDDL, and a second electrode of the fifth transistor ST5 may be connected to the first node N1. The second electrode of the fifth transistor ST5 may be connected to the first electrode of the first transistor ST1 and the second electrode of the second transistor ST2 through the first node N1. For example, the first and second electrodes of the fifth transistor ST5 may be source and drain electrodes, respectively, but the present disclosure is not limited thereto.

The sixth transistor ST6 may be turned on in response to the emission signal from the emission control line EML to electrically connect the second node N2 which is the second electrode of the first transistor ST1 and the fourth node N4 which is the first electrode of the light-emitting element ED. A gate electrode of the sixth transistor ST6 may be connected to the emission control line EML, a first electrode of the sixth transistor ST6 may be connected to the second node N2, and a second electrode of the sixth transistor ST6 may be connected to the fourth node N4. The first electrode of the sixth transistor ST6 may be connected to the second electrode of the first transistor ST1 and the first electrode of the third transistor ST3 through the second node N2. The second electrode of the sixth transistor ST6 may be connected to the first electrode of the light-emitting element ED and a first electrode of the seventh transistor ST7 through the fourth node N4. For example, the first and second electrodes of the sixth transistor ST6 may be source and drain electrodes, respectively, but the present disclosure is not limited thereto.

When the fifth transistor ST5, the first transistor ST1, and the sixth transistor ST6 are all turned on, the diving current Isd may be applied to the light-emitting element ED.

The seventh transistor ST7 may be turned on in response to a fourth gate signal from the fourth gate line GBL to electrically connect the second initialization voltage line VIL2 and the fourth node N4 which is the first electrode of the light-emitting element ED. As the seventh transistor ST7 is turned on in response to the fourth gate signal, the first electrode of the light-emitting element ED may be discharged to as low as a second initialization voltage. A gate electrode of the seventh transistor ST7 may be connected to the fourth gate line GBL, a first electrode of the seventh transistor ST7 may be connected to the fourth node N4, and a second electrode of the seventh transistor ST7 may be connected to the second initialization voltage line VIL2. The first electrode of the seventh transistor ST7 may be connected to the first electrode of the light-emitting element ED and the second electrode of the sixth transistor ST6 through the fourth node N4.

The first, second, fifth, sixth, and seventh transistors ST1, ST2, ST5, ST6, and ST7 may include silicon (Si)-based semiconductor regions. For example, the first, second, fifth, sixth, seventh, and eighth transistors ST1, ST2, ST5, ST6, and ST7 may include semiconductor regions formed of low-temperature polycrystalline silicon (LTPS). The semiconductor regions formed of LTPS may have excellent electron mobility and turn-on characteristics. As the display device 10 includes the first, second, fifth, sixth, and seventh transistors ST1, ST2, ST5, ST6, and ST7 with excellent turn-on characteristics, the display device 10 can stably and efficiently drive the pixel SP.

The first, second, fifth, sixth, and seventh transistors ST1, ST2, ST5, ST6, and ST7 may be p-type transistors. For example, the current may flow through each of the first, second, fifth, sixth, and seventh transistors ST1, ST2, ST5, ST6, and ST7 in response to a gate-low voltage applied to their gate electrode.

The third and fourth transistors ST3 and ST4 may include oxide-based semiconductor regions. For example, each of the third and fourth transistors ST3 and ST4 may have a coplanar structure in which a gate electrode is disposed above an oxide-based semiconductor region. Transistors with coplanar structures can have excellent leakage current characteristics and can operate at low frequencies to reduce power consumption. As the third and fourth transistors ST3 and ST4 with excellent leakage current characteristics are provided, leakage current within the pixel SP can be prevented, and the voltage in the pixel SP can be stably maintained.

The third and fourth transistors ST3 and ST4 may be n-type transistors. For example, the current may flow through each of the third and fourth transistors ST3 and ST4 in response to a gate-high voltage applied to their gate electrode.

The capacitor CST may be connected between the third node N3 which is the gate electrode of the first transistor ST1 and the driving voltage line VDDL. For example, the first capacitor electrode of the capacitor CST may be connected to the third node N3 and a second capacitor electrode of the capacitor CST may be connected to the driving voltage line VDDL. Accordingly, the potential difference between the driving voltage line VDDL and the gate electrode of the first transistor ST1 can be maintained.

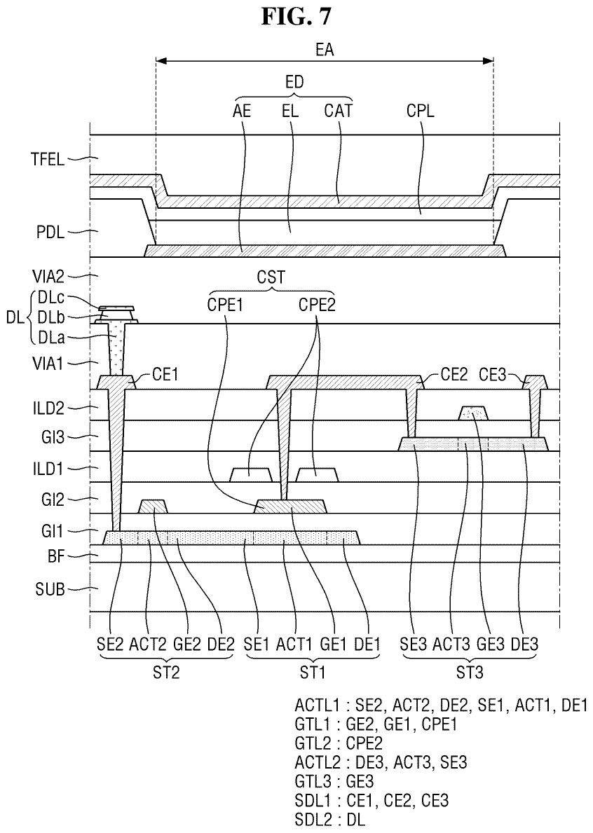

FIG. 7 is a cross-sectional view illustrating a pixel SP of the display device according to an embodiment of the present disclosure.

Referring to FIG. 7, the display panel 100 may include the substrate SUB, a buffer layer BF, a first active layer ACTL1, a first gate insulating layer GI1, a first gate layer GTL1, a second gate insulating layer GI2, a second gate layer GTL2, a first interlayer insulating layer ILD1, a second active layer ACT2, a third gate insulating layer GI3, a third gate layer GTL3, a second interlayer insulating layer ILD2, a first source metal layer SDL1, a first via layer VIA1, a second source metal layer SDL2, a second via layer VIA2, the pixel-defining film PDL, a light-emitting element ED, a capping layer CPL, and an encapsulation layer TFEL.

The substrate SUB may be a base substrate or member. The substrate SUB may be a flexible substrate capable of bending, folding, or rolling. For example, the substrate SUB may include a polymer resin such as PI, but the present disclosure is not limited thereto. In another example, the substrate SUB may include a glass or metal material.

The buffer layer BF may be disposed on the substrate SUB. For example, the buffer layer BF may include an inorganic film capable of preventing the penetration of air or moisture. For example, the buffer layer BF may include a plurality of inorganic films that are alternately stacked.

The first active layer ACTL1 may be disposed on the buffer layer BF. The first active layer ACTL1 may include a Si-based material. For example, the first active layer ACTL1 may be formed of LTPS. The first active layer ACTL1 may include a semiconductor region ACT1, a first electrode SE1, a second electrode DE1 of a first transistor ST1, and a semiconductor region ACT2, a first electrode SE2, and a second electrode DE2 of a second transistor ST2.

The first gate insulating layer GI1 may be disposed on the first active layer ACTL1. The first gate insulating layer GI1 may insulate the first active layer ACTL1 from the first gate layer GTL1.

The first gate layer GTL1 may be disposed on the first gate insulating layer GI1. The first gate layer GTL1 may include a gate electrode GE1 of the first transistor ST1, a gate electrode GE2 of the second transistor ST2, and a first capacitor electrode CPE1. The gate electrode GE1 of the first transistor ST1 may be a portion of the first capacitor electrode CPE1, and the gate electrode GE2 of the second transistor ST2 may be a portion of a first gate line GWL.

The second gate insulating layer GI2 may be disposed on the first gate layer GTL1. The second gate insulating layer GI2 may insulate the first gate layer GTL1 from the second gate layer GTL2.

The second gate layer GTL2 may be disposed on the second gate insulating layer GI2. The second gate layer GTL2 may include a second capacitor electrode CPE2. The second capacitor electrode CPE2 may overlap with the first capacitor electrode CPE1 in a plan view.

The first interlayer insulating layer ILD1 may be disposed on the second gate layer GTL2. The first interlayer insulating layer ILD1 may insulate the second gate layer GTL2 from the second active layer ACTL2.

The second active layer ACTL2 may be disposed on the first interlayer insulating layer ILD1. The second active layer ACTL2 may include an oxide-based material. The second active layer ACTL2 may include a semiconductor region ACT3 of a third transistor ST3, a first electrode DE3, and a second electrode SE3.

The third gate insulating layer GI3 may be disposed on the second active layer ACTL2. The third gate insulating layer GI3 may insulate the second active layer ACTL2 from the third gate layer GTL3.

The third gate layer GTL3 may be disposed on the third gate insulating layer GI3. The third gate layer GTL3 may include a gate electrode GE3 of the third transistor ST3. The gate electrode GE3 of the third transistor ST3 may be a portion of a second gate line GCL.

The second interlayer insulating layer ILD2 may be disposed on the third gate layer GTL3. The second interlayer insulating layer ILD2 may insulate the third gate layer GTL3 from the first source metal layer SDL1.

The first source metal layer SDL1 may be disposed on the second interlayer insulating layer ILD2. The first source metal layer SDL1 may include first through third connection electrodes CE1 through CE3. The first connection electrode CE1 may electrically connect a data line DL and the first electrode SE2 of the second transistor ST2. The second connection electrode CE2 may electrically connect the first capacitor electrode CPE1 and the second electrode SE3 of the third transistor ST3. The third connection electrode CE3 may electrically connect the first electrode DE3 of the third transistor ST3 and the second electrode DE1 of the first transistor ST1.

The first via layer VIA1 may be disposed on the first source metal layer SDL1. The first via layer VIA1 may insulate the first source metal layer SDL1 from the second source metal layer SDL2. The top surface of the first via layer VIA1 may be flat. The first via layer VIA1 may include an organic insulating material such as PI.

The second source metal layer SDL2 may be disposed on the first via layer VIA1. The second source metal layer SDL2 may include the data line DL. The data line DL may include a first layer DLa, a second layer DLb, and a third layer DLc. The first layer DLa may be directly disposed on the first via layer VIA1 and may fill a contact hole of the first via layer VIA1 to contact the first connection electrode CE1. The second layer DLb may be disposed on the first layer DLa, and the third layer DLc may be disposed on the second layer DLb.

The second via layer VIA2 may be disposed on the second source metal layer SDL2. The second via layer VIA2 may insulate the second source metal layer SDL2 and a pixel electrode AE. The top surface of the second via layer VIA2 may be flat. The second via layer VIA2 may include an organic insulating material such as PI.

The pixel-defining film PDL may be disposed on the second via layer VIA2. The pixel-defining film PDL may define emission areas EA. The pixel-defining film PDL may include an organic insulating material such as PI.

The light-emitting element ED may include the pixel electrode AE, a light-emitting layer EL, and a common electrode CAT. The pixel electrode AE may be disposed on the second via layer VIA2. The pixel electrode AE may be disposed in any one of the emission areas EA defined by the pixel-defining film PDL. The pixel electrode AE may receive driving current from the pixel circuit of the pixel SP.

The light-emitting layer EL may be disposed on the pixel electrode AE. For example, the light-emitting layer EL may be an organic light-emitting layer formed of an organic material, but the present disclosure is not limited thereto. In this example, if the pixel circuit of the pixel SP applies a predetermined voltage to the pixel electrode AE and the common electrode CAT1 receives a common voltage or a cathode voltage, both holes and electrons may move through a hole transport layer and an electron transport layer, respectively, in the organic light-emitting layer EL and may combine together in the organic light-emitting layer EL, thereby emitting light.

The common electrode CAT1 may be disposed on the capping layer CPL. For example, the common electrode CAT1 may be implemented in the form of an electrode common to all pixels SP without being separated for each pixel SP. The common electrode CAT1 of the pixel SP may be electrically insulated from the common electrode of a fingerprint sensor OPD. The common electrode CAT1 of the light-emitting element ED may be directly electrically connected to a low-potential line VSSL.

The capping layer CPL may be disposed on the light-emitting layer EL in the emission area EA and may be disposed on the pixel-defining film PDL around the emission area EA. The capping layer CPL may include an inorganic insulating material and can prevent damage to the light-emitting layer EL from external factors.

The encapsulation layer TFEL may be disposed on the common electrode CAT1 and may cover the light-emitting element ED. The encapsulation layer TFEL may include at least one inorganic film to prevent the penetration of oxygen or moisture into the light-emitting element ED. The encapsulation layer TFEL may include at least one organic film to protect the light-emitting element ED from foreign substances such as dust.

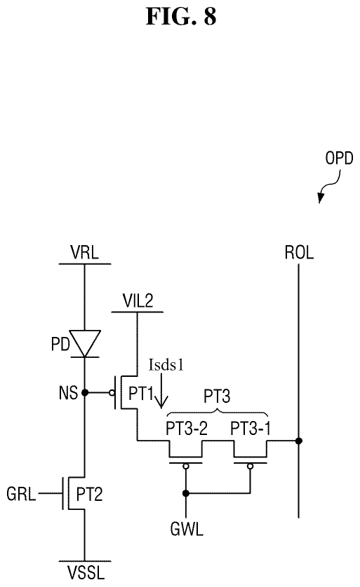

FIG. 8 is a circuit diagram illustrating a fingerprint sensor of the display device according to an embodiment of the present disclosure.

Referring to FIG. 8, a fingerprint sensor OPD may be connected to a first gate line GWL, a reset signal line GRL, a reset voltage line VRL, a second initialization voltage line VIL2, and a read-out line ROL.

The fingerprint sensor OPD may include a light-receiving element PD and a sensor circuit driving the light-receiving element PD. The sensor circuit may include first through third sensor transistors PT1 through PT3.

The first sensor transistor PT1 may include a gate electrode, a first electrode, and a second electrode. The gate electrode of the first sensor transistor PT1 may be connected to a sensor node NS, the first electrode may be connected to the third sensor transistor PT3, and the second electrode of the first sensor transistor PT1 may be connected to the second initialization voltage line VIL2. The first sensor transistor PT1 may control source-drain current Isds1 (hereinafter referred to as “sensing current”) based on the voltage of the sensor node NS which is a node connected to the second electrode of the light-receiving element PD. The sensing current Isds1 may be proportional to the square of the difference between a voltage Vgs across the gate and source electrodes of the first sensor transistor PT1 and a threshold voltage Vth of the first sensor transistor PT1, i.e., Isds1=k′×(Vgs−Vth)² where k′ is a proportional coefficient determined by the structure and physical characteristics of the first sensor transistor PT1, Vgs is the gate-source voltage of the first sensor transistor PT1, and Vth is the threshold voltage of the first sensor transistor PT1. The first electrode of the first sensor transistor PT1 may be, but is not limited to, a source electrode, and the second electrode of the first sensor transistor PT1 may be, but is not limited to, a drain electrode.

The second sensor transistor PT2 may be turned on by a reset signal from the reset signal line GRL to electrically connect the sensor node NS and a low-potential line VSSL. The gate electrode of the second sensor transistor PT2 may be connected to the reset signal line GRL, the first electrode of the second sensor transistor PT2 may be connected to the sensor node NS, and the second electrode of the second sensor transistor PT2 may be connected to the low-potential line VSSL. The second electrode of the second sensor transistor PT2 may receive a low-potential voltage from the low-potential line VSSL. The first electrode of the second sensor transistor PT2 may be connected to both the second electrode of the light-receiving element PD and the gate electrode of the first sensor transistor PT1 through the sensor node NS. The first electrode of the second sensor transistor PT2 may be, but is not limited to, a drain electrode, and the second electrode of the second sensor transistor PT2 may be, but is not limited to, a source electrode.

The third sensor transistor PT3 may be turned on in response to a first gate signal from the first gate line GWL to electrically connect the first electrode of the first sensor transistor PT1 and the read-out line ROL. The third sensor transistor PT3 may include a (3-1)-th sensor transistor PT3-1 and a (3-2)-th sensor transistor PT3-2. The (3-1)-th and (3-2)-th sensor transistors PT3-1 and PT3-2 may be connected in series between the first electrode of the first sensor transistor PT1 and the read-out line ROL. The gate electrodes of the (3-1)-th and (3-2)-th sensor transistors PT3-1 and PT3-2 may be integrally formed and electrically connected to the first gate line GWL. The first electrode of the (3-1)-th sensor transistor PT3-1 may be connected to the read-out line ROL, and the second electrode of the (3-2)-th sensor transistor PT3-2 may be connected to the first electrode of the first sensor transistor PT1. The second electrodes of the (3-1)-th and (3-2)-th sensor transistors PT3-1 and PT3-2 may be integrally formed. The first electrodes of the (3-1)-th and (3-2)-th sensor transistors PT3-1 and PT3-2 may be, but are not limited to, source electrodes, and the second electrodes of the (3-1)-th and (3-2)-th sensor transistors PT3-1 and PT3-2 may be, but are not limited to, drain electrodes.

The light-receiving element PD may recognize the pattern of the user's fingerprint based on light reflected from the user's finger. The first electrode of the light-receiving element PD may be connected to the reset voltage line VRL, and the second electrode of the light-receiving element PD may be connected to the sensor node NS, which is a node connected to the gate electrode of the first sensor transistor PT1. For example, the first electrode of the light-receiving element PD may be, but is not limited to, a sensor electrode, and the second electrode of the light-receiving element PD may be, but is not limited to, a common electrode. When the user's finger contacts the display panel 100, the light-receiving element PD may receive light reflected by the ridges and/or valleys of the finger. Light output from the light-emitting element ED may be reflected by the ridges and/or valleys of the finger of the user and reach the light-receiving element PD. The light-receiving element PD may convert the energy of light into an electrical signal (i.e., current or voltage), and the electrical signal may flow as a reverse bias current from the sensor node NS to the reset voltage line VRL. For example, when the light-receiving element PD receives light and an electric field is generated between the first and second electrodes of the light-receiving element PD, current may flow through the light-receiving element PD in proportion to the amount of light received, and the voltage at the sensor node NS may decrease. Therefore, when the light-receiving element PD receives light, the voltage at the sensor node NS may decrease, and the magnitude of the sensing current (or the source-drain current Isd) of the first sensor transistor PT1 may increase. The sensing current of the first sensor transistor PT1 may be supplied to the display driver 200 as a sensing signal through the third sensor transistor PT3 and the read-out line ROL.

The first and third sensor transistors PT1 and PT3 may include Si-based semiconductor regions. The semiconductor regions of the first and third sensor transistors PT1 and P3 may be disposed in the first active layer ACTL1 of FIG. 7. For example, the first and third sensor transistors PT1 and PT3 may include semiconductor regions formed of LTPS. The semiconductor regions formed of LTPS may have excellent electron mobility and turn-on characteristics. As the display device 10 includes the first and third sensor transistors PT1 and PT3 with excellent turn-on characteristics, the display device 10 can stably and efficiently drive multiple fingerprint sensors OPD.

The first and third sensor transistors PT1 and PT3 may be p-type transistors. For example, the current may flow through each of the first and third sensor transistors PT1 and PT3 in response to a gate-low voltage applied to their gate electrode.

The second sensor transistor PT2 may include an oxide-based semiconductor region. For example, the second sensor transistor PT2 may have a coplanar structure where its gate electrode is disposed on the oxide-based semiconductor region. Transistors with coplanar structures can have excellent leakage current characteristics and can operate at low frequencies to reduce power consumption. Therefore, as the second sensor transistor PT2 with excellent leakage current characteristics is provided, leakage current within the fingerprint sensor OPD can be prevented, and the voltage at the sensor node NS can be stably maintained.

The second sensor transistor PT2 may be an n-type transistor. For example, the current may flow through the second sensor transistor PT2 in response to a gate-high voltage applied to its gate electrode.

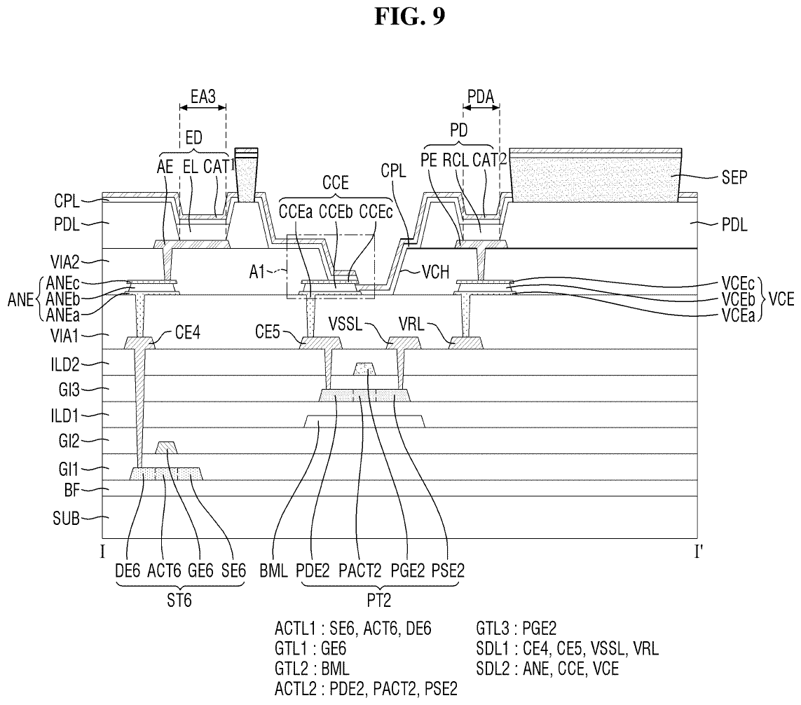

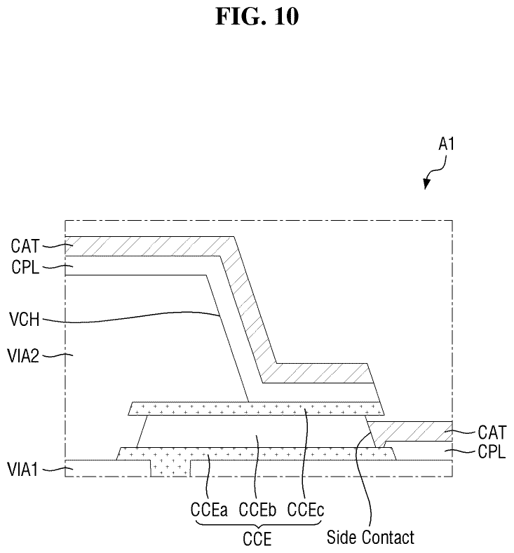

FIG. 9 is a cross-sectional view taken along line I-I′ of FIG. 5, and FIG. 10 is an enlarged cross-sectional view of an area A1 of FIG. 9. Descriptions of features that have already been described so far will be simplified or omitted.

Referring to FIGS. 9 and 10, the display panel 100 may include the substrate SUB, the buffer layer BF, the first active layer ACTL1, the first gate insulating layer GI1, the first gate layer GTL1, the second gate insulating layer GI2, the second gate layer GTL2, the first interlayer insulating layer ILD1, the second active layer ACT2, the third gate insulating layer GI3, the third gate layer GTL3, the second interlayer insulating layer ILD2, the first source metal layer SDL1, the first via layer VIA1, the second source metal layer SDL2, the second via layer VIA2, the pixel-defining film PDL, a light-emitting element ED, a light-receiving element PD, the capping layer CPL, and a separation portion SEP.

The first active layer ACTL1 may be disposed on the buffer layer BF. The first active layer ACTL1 may include a Si-based material. For example, the first active layer ACTL1 may be formed of LTPS. The first active layer ACTL1 may include a semiconductor region ACT6, a first electrode SE6, and a second electrode DE6 of a sixth transistor ST6.

The first gate layer GTL1 may be disposed on the first gate insulating layer GI1. The first gate layer GTL1 may include a gate electrode GE6 of the sixth transistor ST6. The gate electrode GE6 of the sixth transistor ST6 may be a portion of an emission control line EML.

The second gate layer GTL2 may be disposed on the second gate insulating layer GI2. The second gate layer GTL2 may include a light-blocking layer BML. The light-blocking layer BML may overlap with a semiconductor region PACT2 of a second sensor transistor PT2 in a plan view. Therefore, the light-blocking layer BML may block light incident from below the second sensor transistor PT2.

The second active layer ACTL2 may be disposed on the first interlayer insulating layer ILD1. The second active layer ACTL2 may include an oxide-based material. The second active layer ACTL2 may include the semiconductor region PACT2, a first electrode PDE2, and a second electrode PSE2 of the second sensor transistor PT2.

The third gate layer GTL3 may be disposed on the third gate insulating layer GI3. The third gate layer GTL3 may include a gate electrode PGE2 of the second sensor transistor PT2. The gate electrode PGE2 of the second sensor transistor PT2 may be a portion of a reset signal line GRL.

The first source metal layer SDL1 may be disposed on the second interlayer insulating layer ILD2. The first source metal layer SDL1 may include a fourth connection electrode CE4, a fifth connection electrode CE5, a low-potential line VSSL, and a reset voltage line VRL. The fourth connection electrode CE4 may electrically connect the second electrode DE6 of the sixth transistor ST6 and an anode connection electrode ANE. The fifth connection electrode CE5 may electrically connect a cathode connection electrode CCE and the first electrode PDE2 of the second sensor transistor PT2. The low-potential line VSSL may supply a low-potential voltage to the second electrode PSE2 of the second sensor transistor PT2. The reset voltage line VRL may supply a reset voltage to a voltage connection electrode VCE.

The second source metal layer SDL2 may be disposed on the first via layer VIA1. The second source metal layer SDL2 may include the anode connection electrode ANE, the cathode connection electrode CCE, and the voltage connection electrode VCE.

The anode connection electrode ANE may electrically connect the fourth connection electrode CE4 and a pixel electrode AE. The anode connection electrode ANE may include a first layer ANEa, a second layer ANEb, and a third layer ANEc. The first layer ANEa may be directly disposed on the first via layer VIA1 and fill a contact hole of the first via layer VIA1 to contact the fourth connection electrode CE4. The second layer ANEb may be disposed on the first layer ANEa. The third layer ANEc may be disposed on the second layer ANEb to contact the pixel electrode AE.

The cathode connection electrode CCE may electrically connect the fifth connection electrode CE5 and a common electrode CAT2 of the light-receiving element PD. The cathode connection electrode CCE may correspond to the sensor node NS of FIG. 8. The cathode connection electrode CCE may include a first layer CCEa, a second layer CCEb, and a third layer CCEc. The first layer CCEa may be directly disposed on the first via layer VIA1 and fill the contact hole of the first via layer VIA1 to contact the fifth connection electrode CE5. The second layer CCEb may be disposed on the first layer CCEa, and the third layer CCEc may be disposed on the second layer CCEb.

The sides of the second layer CCEb may be inwardly recessed from the sides of each of the first and third layers CCEa and CCEc. As the sides of the third layer CCEc protrude from the sides of the second layer CCEb, the third layer CCEc may include overhangs or protruded tips. The capping layer CPL and the common electrode CAT2 may be disconnected around the overhangs due to the overhangs of the third layer CCEc. A first portion of the common electrode CAT2 may be disposed on the third layer CCEc, and a second portion of the common electrode CAT2 may be disconnected from the first portion of the common electrode CAT2 and directly contact the sides of the second layer CCEb.

The thickness of the second layer CCEb may be greater than the thickness of each of the first and third layers CCEa and CCEc. For example, the first layer CCEa may include titanium (Ti), the second layer CCEb may include aluminum (A1) for high conductivity, and the third layer CCEc may include Ti.

A portion of the cathode connection electrode CCE may be exposed through a contact hole VCH of the second via layer VIA2 and an opening of the pixel-defining film PDL. The sides of the second layer CCEb and the sides of the common electrode CAT2 of the light-receiving element PD may directly contact in the via contact hole VCH. Therefore, the cathode connection electrode CCE and the common electrode CAT2 of the light-receiving element PD may be electrically connected through side contacts.

The common electrode CAT2 of the light-receiving element PD may be disposed in an opening of the pixel-defining film PDL and the via contact hole VCH to directly contact the sides of the cathode connection electrode CCE. The common electrode CAT2 may supply the current flowing through the light-receiving element PD to the cathode connection electrode CCE. Thus, when the light-receiving element PD receives light, current may be supplied to the second sensor transistor PT2 through the common electrode CAT, the cathode connection electrode CCE, and the fifth connection electrode CE5.

The voltage connection electrode VCE may electrically connect the reset voltage line VRL and a sensor electrode PE. The voltage connection electrode VCE may include a first layer VCEa, a second layer VCEb, and a third layer VCEc. The first layer VCEa may be directly disposed on the first via layer VIA1 and fill the contact hole of the first via layer VIA1 to contact the reset voltage line VRL. The second layer VCEb may be disposed on the first layer VCEa. The third layer VCEc may be disposed on the second layer VCEb to contact the sensor electrode PE.

The pixel-defining film PDL may be disposed on the second via layer VIA2. The pixel-defining film PDL may define an emission area EA (e.g., a third emission area EA3) and a sensor area PDA. The emission area EA may emit light from the light-emitting element ED, and the sensor area PDA may receive light reflected by a finger. The pixel-defining film PDL may include an opening exposing the via contact hole VCH of the second via layer VIA2. The pixel-defining film PDL may include an organic insulating material such as PI.

The light-receiving element PD of a fingerprint sensor OPD may include the sensor electrode PE, a light-receiving layer RCL, and the common electrode CAT2. The sensor electrode PE may be disposed on the second via layer VIA2 in the same layer as the pixel electrode AE of the light-emitting element ED. The sensor electrode PE may be disposed in the sensor area PDA defined by the pixel-defining film PDL.

The light-receiving layer RCL may be disposed on the sensor electrode PE. When the user's finger contacts the display panel 100, the light-receiving layer RCL may receive light reflected by the finger's ridges and/or valleys. Light emitted from the light-emitting element ED may be reflected by the finger's ridges and/or valleys and reach the light-receiving layer RCL. The light-receiving element PD may convert the energy of light into an electrical signal (i.e., current or voltage), and the electrical signal may flow to the second sensor transistor PT2 through the common electrode CAT, the cathode connection electrode CCE, and the fifth connection electrode CE5. For example, when the light-receiving element PD receives light, current may flow to the light-receiving element PD in proportion to the amount of light received.

The common electrode CAT may be disposed on the capping layer CPL. For example, the common electrode CAT may be disconnected around the separation portion SEP. The common electrode CAT2 may be disposed in the opening of the pixel-defining film PDL and the via contact hole VCH to directly contact the sides of the cathode connection electrode CCE. The common electrode CPD may supply the current flowing through the light-receiving element PD to the cathode connection electrode CCE. Thus, when the light-receiving element PD receives light, current may be supplied to the second sensor transistor PT2 through the common electrode CAT2, the cathode connection electrode CCE, and the fifth connection electrode CE5. The sides of the second layer CCEb of the cathode connection electrode CCE may directly contact the sides of the common electrode CAT2 of the light-receiving element PD in the via contact hole VCH. Thus, the cathode connection electrode CCE and the common electrode CAT2 of the light-receiving element PD may be electrically connected through side contacts.

The capping layer CPL may be disposed on the light-receiving layer RCL in the sensor area PDA and may be disposed on the pixel-defining film PDL around the sensor area PDA. The capping layer CPL may be disposed on the second via layer VIA2, in the opening of the pixel-defining film PDL, and may be disposed on the cathode connection electrode CCE or the first via layer VIA1 in the via contact hole VCH. The capping layer CPL may include an inorganic insulating material and can prevent damage to the light-receiving layer RCL from external factors.

The separation portion SEP may be disposed on the pixel-defining film PDL to completely surround sensor area PDA. The separation portion SEP may separate the emission area EA and the sensor area PDA. The separation portion SEP may separate the common electrode CAT1 of the light-emitting element ED and the common electrode CAT2 of the light-receiving element PD that are both deposited at the front of the display panel 100. Thus, the common electrodes CAT1 of the light-emitting element ED and the common electrode CAT2 of the light-receiving element PD may be electrically insulated.

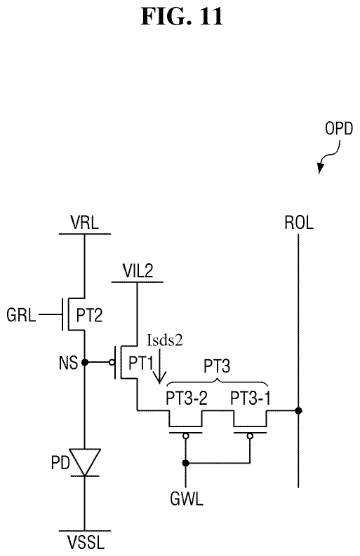

FIG. 11 is a circuit diagram illustrating a fingerprint sensor of a display device according to another embodiment of the present disclosure.

Referring to FIG. 11, a fingerprint sensor OPD may be connected to a first gate line GWL, a reset signal line GRL, a reset voltage line VRL, a second initialization voltage line VIL2, and a read-out line ROL.

The fingerprint sensor OPD may include a light-receiving element PD and a sensor circuit driving the light-receiving element PD. The sensor circuit may include first through third sensor transistors PT1 through PT3.

The first sensor transistor PT1 may include a gate electrode, a first electrode, and a second electrode. The gate electrode of the first sensor transistor PT1 may be connected to a sensor node NS, the first electrode may be connected to the third sensor transistor PT3, and the second electrode of the first sensor transistor PT1 may be connected to the second initialization voltage line VIL2. The first sensor transistor PT1 may control source-drain current Isds2 (hereinafter referred to as “sensing current”) based on the voltage of the sensor node NS which is the first electrode of the light-receiving element PD. The sensing current Isds2 may be proportional to the square of the difference between a voltage Vgs across the gate and source electrodes of the first sensor transistor PT1 and a threshold voltage Vth of the first sensor transistor PT1, i.e., Isds2=k′×(Vgs−Vth)² where k′ is a proportional coefficient determined by the structure and physical characteristics of the first sensor transistor PT1, Vgs is the gate-source voltage of the first sensor transistor PT1, and Vth is the threshold voltage of the first sensor transistor PT1. The first electrode of the first sensor transistor PT1 may be, but is not limited to, a source electrode, and the second electrode of the first sensor transistor PT1 may be, but is not limited to, a drain electrode.

The second sensor transistor PT2 may be turned on in response to a reset signal from the reset signal line GRL to supply a reset voltage to the sensor node NS. The gate electrode of the second sensor transistor PT2 may be connected to the reset signal line GRL, the first electrode of the second sensor transistor PT2 may be connected to the reset voltage line VRL, and the second electrode of the second sensor transistor PT2 may be connected to the sensor node NS. The second electrode of the second sensor transistor PT2 may be connected to both the first electrode of the light-receiving element PD and the gate electrode of the first sensor transistor PT1 through the sensor node NS. The first electrode of the second sensor transistor PT2 may be, but is not limited to, a drain electrode, and the second electrode of the second sensor transistor PT2 may be, but is not limited to, a source electrode.

The third sensor transistor PT3 may be turned on by a first gate signal from the first gate line GWL to electrically connect the first electrode of the first sensor transistor PT1 and the read-out line ROL. The third sensor transistor PT3 may include a (3-1)-th sensor transistor PT3-1 and a (3-2)-th sensor transistor PT3-2. The (3-1)-th and (3-2)-th sensor transistors PT3-1 and PT3-2 may be connected in series between the first electrode of the first sensor transistor PT1 and the read-out line ROL. The gate electrodes of the (3-1)-th and (3-2)-th sensor transistors PT3-1 and PT3-2 may be integrally formed and electrically connected to the first gate line GWL.

The first electrode of the (3-1)-th sensor transistor PT3-1 may be connected to the read-out line ROL, and the second electrode of the (3-2)-th sensor transistor PT3-2 may be connected to the first electrode of the first sensor transistor PT1. The second electrodes of the (3-1)-th and (3-2)-th sensor transistors PT3-1 and PT3-2 may be integrally formed. The first electrodes of the (3-1)-th and (3-2)-th sensor transistors PT3-1 and PT3-2 may be, but are not limited to, source electrodes, and the second electrodes of the (3-1)-th and (3-2)-th sensor transistors PT3-1 and PT3-2 may be, but are not limited to, drain electrodes.

The light-receiving element PD may recognize the pattern of the user's fingerprint based on light reflected from the user's finger. The first electrode of the light-receiving element PD may be connected to the sensor node NS which is the gate electrode of the first sensor transistor PT1 and the second electrode of the light-receiving element PD may receive a low-potential voltage from the low-potential line VSSL.

When the user's finger contacts the display panel 100, the light-receiving element PD may receive light reflected by the ridges and/or valleys of the finger. Light output from the light-emitting element ED may be reflected by the ridges and/or valleys of the finger of the user and reach the light-receiving element PD. The light-receiving element PD may convert the energy of light into an electrical signal (i.e., current or voltage), and the electrical signal may flow as a reverse bias current from the low-potential line VSSL to the sensor node NS. For example, when the light-receiving element PD receives light and an electric field is generated between the first and second electrodes of the light-receiving element PD, current may flow through the light-receiving element PD in proportion to the amount of light received, and the voltage at the sensor node NS may decrease. Therefore, when the light-receiving element PD receives light, the voltage at the sensor node NS may decrease, and the magnitude of the sensing current (or the source-drain current Isd) of the first sensor transistor PT1 may increase. The sensing current of the first sensor transistor PT1 may be supplied to the display driver 200 as a sensing signal through the third sensor transistor PT3 and the read-out line ROL.

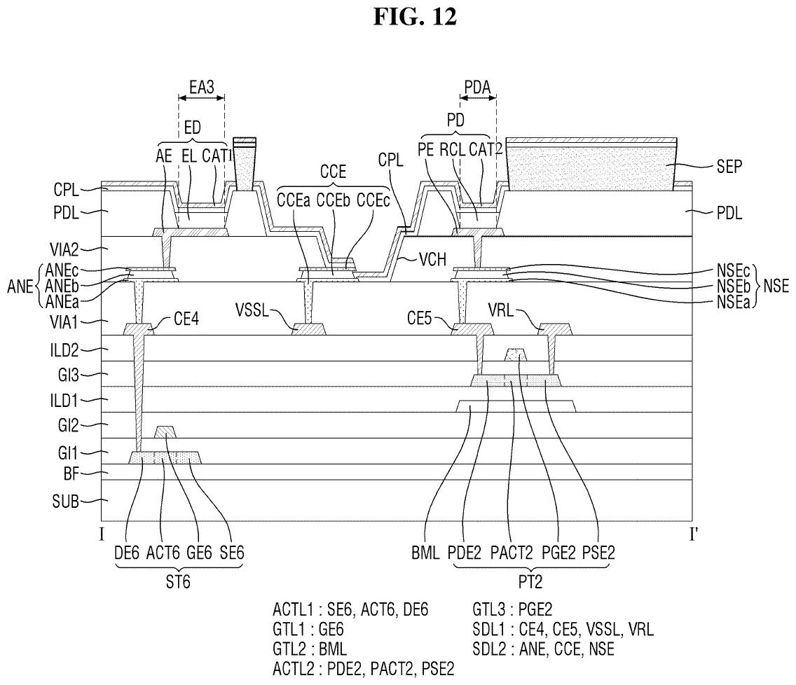

FIG. 12 is another cross-sectional view taken along line I-I′ of FIG. 5. Descriptions of features that have already been described so far will be simplified or omitted.

Referring to FIG. 12, the display panel 100 may include the substrate SUB, the buffer layer BF, the first active layer ACTL1, the first gate insulating layer GI1, the first gate layer GTL1, the second gate insulating layer GI2, the second gate layer GTL2, the first interlayer insulating layer ILD1, the second active layer ACT2, the third gate insulating layer GI3, the third gate layer GTL3, the second interlayer insulating layer ILD2, the first source metal layer SDL1, the first via layer VIA1, the second source metal layer SDL2, the second via layer VIA2, the pixel-defining film PDL, a light-emitting element ED, a light-receiving element PD, the capping layer CPL, and a separation portion SEP.

The second active layer ACTL2 may be disposed on the first interlayer insulating layer ILD1. The second active layer ACTL2 may include an oxide-based material. The second active layer ACTL2 may include the semiconductor region PACT2, a first electrode PDE2, and a second electrode PSE2 of the second sensor transistor PT2.

The third gate layer GTL3 may be disposed on the third gate insulating layer GI3. The third gate layer GTL3 may include a gate electrode PGE2 of the second sensor transistor PT2. The gate electrode PGE2 of the second sensor transistor PT2 may be a portion of a reset signal line GRL.

The first source metal layer SDL1 may be disposed on the second interlayer insulating layer ILD2. The first source metal layer SDL1 may include a fourth connection electrode CE4, a fifth connection electrode CE5, a low-potential line VSSL, and a reset voltage line VRL. The fourth connection electrode CE4 may electrically connect the second electrode DE6 of the sixth transistor ST6 and an anode connection electrode ANE. The fifth connection electrode CE5 may electrically connect the second electrode PSE2 of the second sensor transistor PT2 and a sensor node electrode NSE. The low-potential line VSSL may supply a low-potential voltage to the cathode connection electrode CCE. The reset voltage line VRL may supply a reset voltage to the first electrode PDE2 of the second sensor transistor PT2.

The second source metal layer SDL2 may be disposed on the first via layer VIA1. The second source metal layer SDL2 may include the anode connection electrode ANE, the sensor node electrode NSE, and the cathode connection electrode CCE.

The sensor node electrode NSE may electrically connect the fifth connection electrode CE5 and a sensor electrode PE. The sensor node electrode NSE may correspond to the sensor node NS of FIG. 11. The sensor node electrode NSE may include a first layer NSEa, a second layer NSEb, and a third layer NSEc. The first layer NSEa may be directly disposed on the first via layer VIA1 and fill a contact hole of the first via layer VIA1 to contact the fifth connection electrode CE5. The second layer NSEb may be disposed on the first layer NSEa. The third layer NSEc may be disposed on the second layer NSEb to contact the sensor electrode PE.

The cathode connection electrode CCE may electrically connect a common electrode CAT2 of the light-receiving element PD and the low-potential line VSSL. The cathode connection electrode CCE may include a first layer CCEa, a second layer CCEb, and a third layer CCEc. The first layer CCEa may be directly disposed on the first via layer VIA1 and fill the contact hole of the first via layer VIA1 to contact the low-potential line VSSL. The second layer CCEb may be disposed on the first layer CCEa, and the third layer CCEc may be disposed on the second layer CCEb.

The sides of the second layer CCEb may be inwardly recessed from the sides of each of the first and third layers CCEa and CCEc. As the sides of the third layer CCEc protrude from the sides of the second layer CCEb, the third layer CCEc may include overhangs or protruded tips. The capping layer CPL and the common electrode CAT may be disconnected due to the overhangs of the third layer CCEc. A portion of the common electrode CAT2 may be disposed on the third layer CCEc, and another portion of the common electrode CAT2 may directly contact the sides of the second layer CCEb.

The thickness of the second layer CCEb may be greater than the thickness of each of the first and third layers CCEa and CCEc. For example, the first layer CCEa may include Ti, the second layer CCEb may include A1 for high conductivity, and the third layer CCEc may include Ti.

A portion of the cathode connection electrode CCE may be exposed through a contact hole VCH of the second via layer VIA2 and an opening of the pixel-defining film PDL. The sides of the second layer CCEb and the sides of the common electrode CAT2 of the light-receiving element PD may directly contact in the via contact hole VCH. Therefore, the cathode connection electrode CCE and the common electrode CAT2 of the light-receiving element PD may be electrically connected through side contacts.

The common electrode CAT2 of the light-receiving element PD may be disposed in an opening of the pixel-defining film PDL and the via contact hole VCH to directly contact the sides of the cathode connection electrode CCE. The common electrode CAT2 may supply the current flowing through the light-receiving element PD to the cathode connection electrode CCE. Thus, when the light-receiving element PD receives light, current may be supplied to the low-potential line VSSL through the common electrode CAT2 and the cathode connection electrode CCE.

The pixel-defining film PDL may be disposed on the second via layer VIA2. The pixel-defining film PDL may define emission areas EA (e.g., a third emission area EA3) and a sensor area PDA. The emission areas EA may emit light from the light-emitting element ED, and the sensor area PDA may receive light reflected by a finger. The pixel-defining film PDL may include an opening exposing the via contact hole VCH of the second via layer VIA2. The pixel-defining film PDL may include an organic insulating material such as PI.

The light-receiving element PD of a fingerprint sensor OPD may include the sensor electrode PE, a light-receiving layer RCL, and the common electrode CAT2. The sensor electrode PE may be disposed on the second via layer VIA2 in the same layer as the pixel electrode AE of the light-emitting element ED. The sensor electrode PE may overlap with the sensor area PDA defined by the pixel-defining film PDL.

The light-receiving layer RCL may be disposed on the sensor electrode PE. When the user's finger contacts the display panel 100, the light-receiving layer RCL may receive light reflected by the finger's ridges and/or valleys. Light emitted from the light-emitting element ED may be reflected by the finger's ridges and/or valleys and reach the light-receiving layer RCL. The light-receiving element PD may convert the energy of light into an electrical signal (i.e., current or voltage), and the electrical signal may flow to the low-potential line VSSL through the common electrode CAT2 and the cathode connection electrode CCE. For example, when the light-receiving element PD receives light, current may flow to the light-receiving element PD in proportion to the amount of light received.

The common electrode CAT2 may be disposed on the capping layer CPL. For example, the common electrode CAT2 may be disconnected around the fingerprint sensor OPD by the separation portion SEP. The common electrode CAT2 may be disposed in the opening of the pixel-defining film PDL and the via contact hole VCH to directly contact the sides of the cathode connection electrode CCE. The common electrode CPD may supply the current flowing through the light-receiving element PD to the cathode connection electrode CCE. Thus, when the light-receiving element PD receives light, current may be supplied to the low-potential line VSSL through the common electrode CAT2 and the cathode connection electrode CCE. The sides of the second layer CCEb of the cathode connection electrode CCE may directly contact the sides of the common electrode CAT2 of the light-receiving element PD in the via contact hole VCH. Thus, the cathode connection electrode CCE and the common electrode CAT2 of the light-receiving element PD may be electrically connected through side contacts.

The capping layer CPL may be disposed on the light-receiving layer RCL, in the sensor area PDA and may be disposed on the pixel-defining film PDL around the sensor area PDA. The capping layer CPL may be disposed on the second via layer VIA2 in the opening of the pixel-defining film PDL and may be disposed on the cathode connection electrode CCE or the first via layer VIA1 in the via contact hole VCH. The capping layer CPL may include an inorganic insulating material and can prevent damage to the light-receiving layer RCL from external factors.

The separation portion SEP may be disposed on the pixel-defining film PDL to completely surround sensor area PDA. The separation portion SEP may separate the emission area EA and the sensor area PDA. The separation portion SEP may separate the common electrodes CAT1 of the light-emitting element ED and the common electrodes CAT2 of the light-receiving element PD that are both deposited at the front of the display panel 100. Thus, the common electrodes CAT1 of the light-emitting element ED and the common electrodes CAT2 of the light-receiving element PD may be electrically insulated.

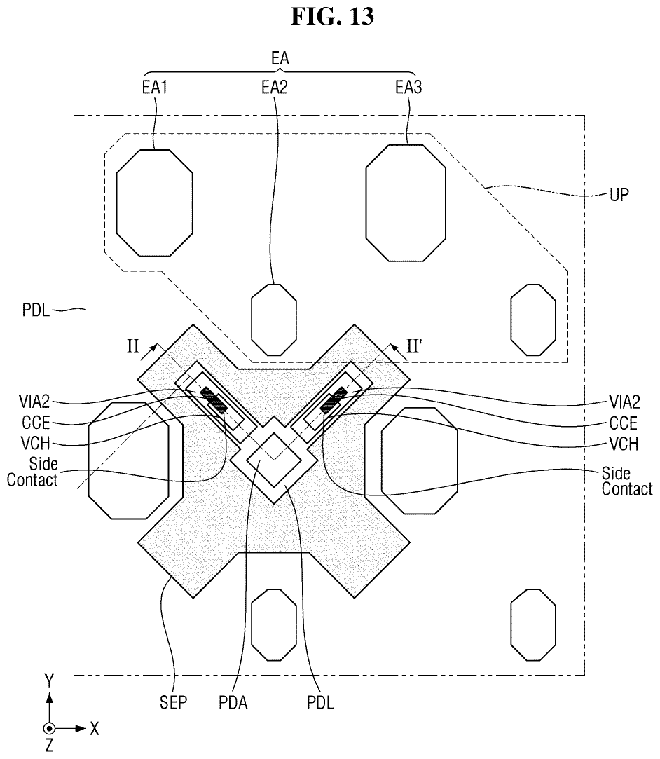

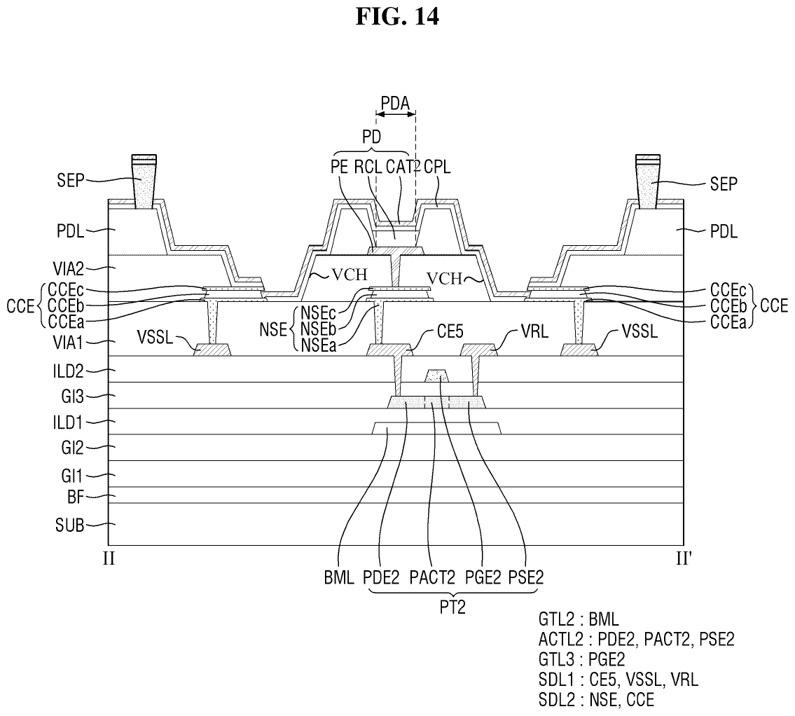

FIG. 13 is a plan view illustrating emission areas, a sensor area, and a separation portion of a display device according to another embodiment of the present disclosure, and FIG. 14 is a cross-sectional view taken along line II-II′ of FIG. 13. Descriptions of features that have already been described so far will be simplified or omitted.

Referring to FIGS. 13 and 14, a display area DA may include emission areas EA and a sensor area PDA. The emission areas EA and the sensor area PDA may be defined by a pixel-defining film PDL.

The sensor area PDA may be surrounded by a first emission area EA1, second emission areas EA2, and a third emission area EA3. The sensor area PDA may be disposed adjacent to the first or third emission areas EA1 or EA3 in an X-axis direction and may be disposed adjacent to the second emission areas EA2 in a Y-axis direction. The sensor area PDA may be spaced apart from other sensor areas PDA with at least one emission area EA disposed therebetween. The sensor area PDA may receive light reflected by a finger of the user.

The emission areas EA and the sensor area PDA may be spaced apart from each other with a separation portion SEP disposed therebetween. The separation portion SEP may separate a common electrode CAT1 of light-emitting elements ED of a pixel SP and a common electrode CAT2 of light-receiving elements PD of a fingerprint sensor OPD. The separation portion SEP may be disposed on a pixel-defining film PDL and may separate the common electrodes CAT1 of the pixel SP and the common electrode CAT2 of the fingerprint sensor OPD that are both disposed on the front surface of the display panel 100. Consequently, the common electrodes CAT1 of the pixel SP and the common electrode CAT2 of the fingerprint sensor OPD may be electrically insulated.

The separation portion SEP may have a closed-loop shape completely surrounding the sensor area PDA. The separation portion SEP may be disposed around the emission areas EA surrounding the sensor area PDA. For example, the separation portion SEP may extend in a direction diagonal to the X- and Y-axis directions to be disposed between first and second emission areas EA1 and EA2. The separation portion SEP may extend in a direction diagonal to the opposite direction of the X-axis direction and the Y-axis direction to be disposed between the second emission area EA2 and a third emission area EA3. Thus, the separation portion SEP may separate the sensor area PDA from the emission areas EA and may be disposed between adjacent emission areas EA. Since the separation portion SEP has a relatively large width between the sensor area PDA and the emission areas EA, the separation portion SEP can secure margins for the pixel-defining film PDL in a high-resolution display device 10.

A second via layer VIA2 may be disposed below the pixel-defining film PDL. Parts of the second via layer VIA2 including areas corresponding to the emission areas EA and the sensor area PDA may be exposed through the openings in the pixel-defining film PDL. Moreover, parts of the second via layer VIA2 other than the areas corresponding to the emission areas EA and the sensor area PDA may also be exposed through the openings in the pixel-defining film PDL. The second via layer VIA2 may include via contact holes VCH. Cathode connection electrodes CCE may be disposed below the second via layer VIA2, and parts of the cathode connection electrodes CCE may be exposed through the via contact holes VCH. The sides of the cathode connection electrodes CCE may directly contact the sides of the common electrode CAT2 of the fingerprint sensor OPD in the respective via contact holes VCH. Thus, the cathode connection electrodes CCE and the common electrode CAT2 of the fingerprint sensor OPD can be electrically connected through side contacts.

For example, one via contact hole VCH may be spaced apart from a sensor area PDA in the diagonal direction between the opposite direction of the X-axis direction and the Y-axis direction and surrounded by a second emission area EA2, a third emission area EA3, and a sensor area PDA, and another via hole VCH may be spaced apart from the sensor area PDA in the diagonal direction between the X- and Y-axis directions and surrounded by a first emission area EA1, the second emission area EA2, and the sensor area PDA. The separation portion SEP may surround these multiple via contact holes VCH, and the common electrode CAT2 of the fingerprint sensor OPD may directly contact the cathode connection electrodes CCE disposed in the respective via contact holes VCH. Accordingly, as the cathode connection electrodes CCE and the common electrode CAT2 of the fingerprint sensor OPD are electrically connected via multiple side contacts, the common electrode CAT2 can easily function as wiring without compromising resolution.

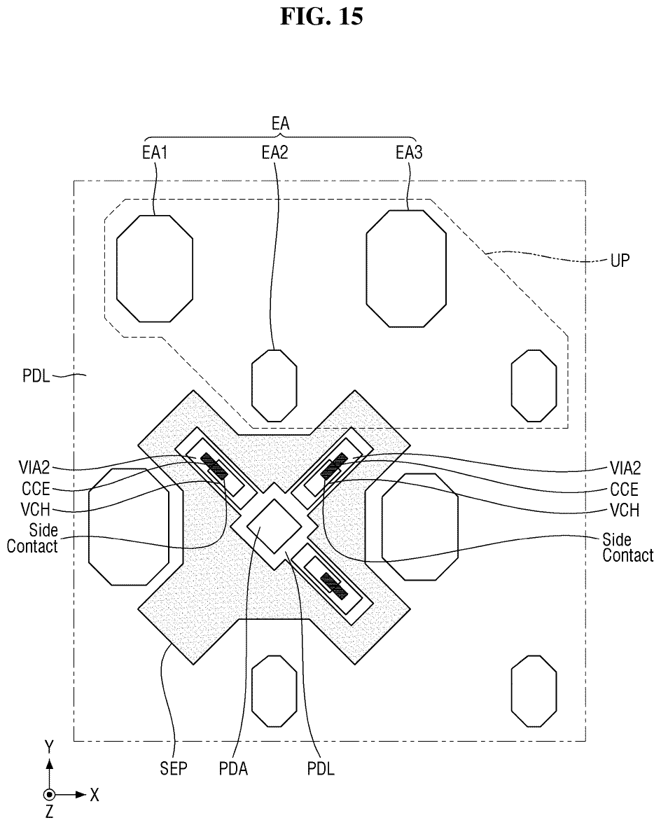

FIG. 15 is a plan view illustrating emission areas, sensor areas, and separation portions of a display device according to another embodiment of the present disclosure.

Referring to FIG. 15, one via contact hole VCH may be spaced apart from a sensor area PDA in a direction diagonal to the opposite direction of an X-axis direction and a Y-axis direction and surrounded by a second emission area EA2, a third emission area EA3, and a sensor area PDA, another via hole VCH may be spaced apart from the sensor area PDA in a direction diagonal to the X-axis direction and the Y-axis direction and surrounded by a first emission area EA1, the second emission area EA2, and the sensor area PDA, and yet another via hole VCH may be spaced apart from the sensor area PDA in a direction diagonal to the X-axis direction and the opposite direction of the Y-axis direction and surrounded by the first emission area EA1, the second emission area EA2, and the sensor area PDA.

A separation portion SEP may surround these multiple via contact holes VCH, and a common electrode CAT2 of a fingerprint sensor OPD may directly contact cathode connection electrodes CCE disposed in the respective via contact holes VCH. Accordingly, as the cathode connection electrodes CCE and the common electrode CAT2 of the fingerprint sensor OPD are electrically connected via multiple side contacts, the common electrode CAT2 can easily function as wiring without compromising resolution.

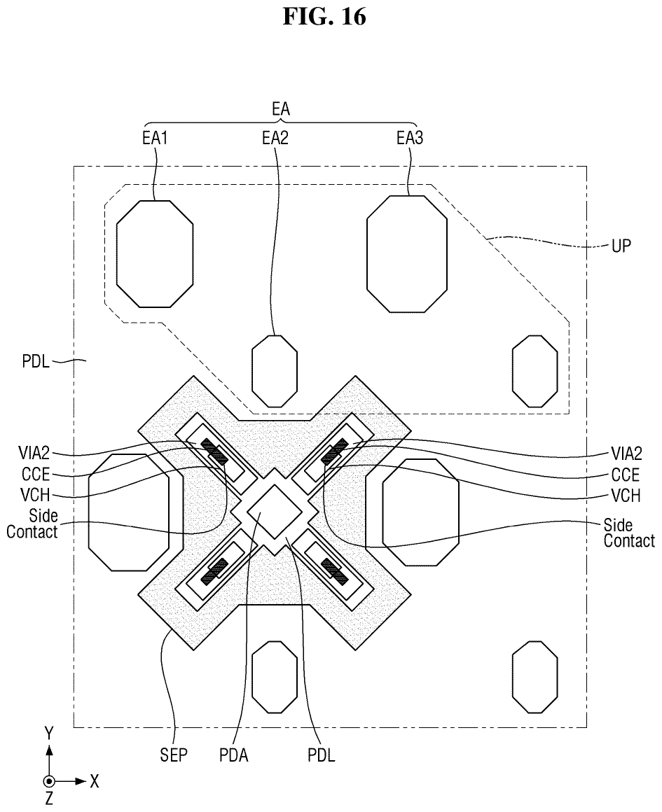

FIG. 16 is a plan view illustrating emission areas, sensor areas, and separation portions of a display device according to another embodiment of the present disclosure.

Referring to FIG. 16, one via contact hole VCH may be spaced apart from a sensor area PDA in a direction diagonal to the opposite direction of an X-axis direction and a Y-axis direction and surrounded by a second emission area EA2, a third emission area EA3, and a sensor area PDA, another via hole VCH may be spaced apart from the sensor area PDA in a direction diagonal to the X-axis direction and the Y-axis direction and surrounded by a first emission area EA1, the second emission area EA2, and the sensor area PDA, yet another via hole VCH may be spaced apart from the sensor area PDA in a direction diagonal to the X-axis direction and the opposite direction of the Y-axis direction and surrounded by the first emission area EA1, the second emission area EA2, and the sensor area PDA, and still another via hole VCH may be spaced apart from the sensor area PDA in a direction diagonal to the opposite directions of the X- and Y-axis directions and surrounded by the second and third emission areas EA2 and EA3 and the sensor area PDA.

A separation portion SEP may surround these multiple via contact holes VCH, and a common electrode CAT2 of a fingerprint sensor OPD may directly contact cathode connection electrodes CCE disposed in the respective via contact holes VCH. Accordingly, as the cathode connection electrodes CCE and the common electrode CAT2 of the fingerprint sensor OPD are electrically connected via multiple side contacts, the common electrode CAT2 can easily function as wiring without compromising resolution.

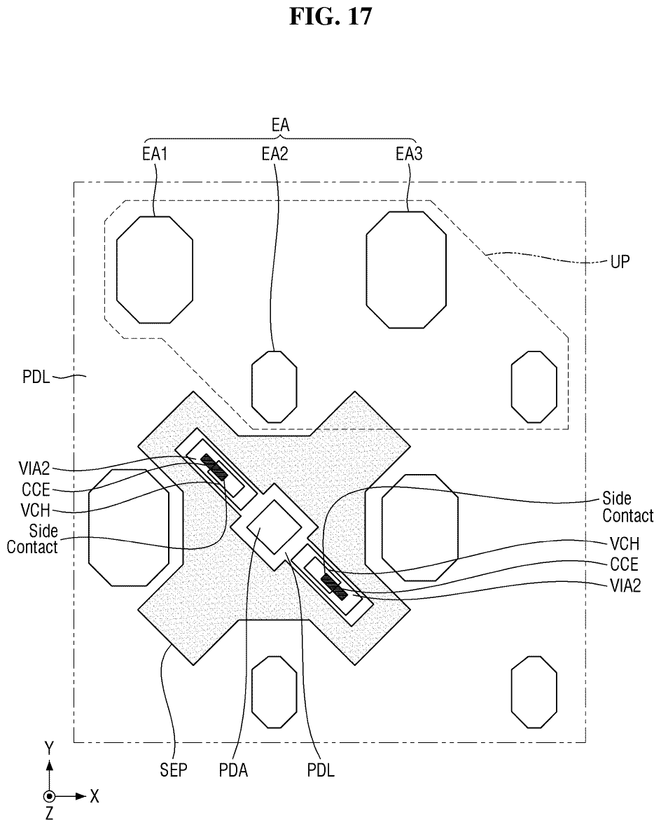

FIG. 17 is a plan view illustrating emission areas, sensor areas, and separation portions of a display device according to another embodiment of the present disclosure.

Referring to FIG. 17, one via contact hole VCH may be spaced apart from a sensor area PDA in a direction diagonal to the opposite direction of an X-axis direction and a Y-axis direction and surrounded by a second emission area EA2, a third emission area EA3, and a sensor area PDA, and another via hole VCH may be spaced apart from the sensor area PDA in a direction diagonal to the X-axis direction and the opposite direction of the Y-axis direction and surrounded by a first emission area EA1, the second emission area EA2, and the sensor area PDA.

A separation portion SEP may surround these multiple via contact holes VCH, and a common electrode CAT2 of a fingerprint sensor OPD may directly contact cathode connection electrodes CCE disposed in the respective via contact holes VCH. Accordingly, as the cathode connection electrodes CCE and the common electrode CAT2 of the fingerprint sensor OPD are electrically connected via multiple side contacts, the common electrode CAT2 can easily function as wiring without compromising resolution.

The display device according to one embodiment of the present disclosure can be applied to various electronic devices. The electronic device according to the one embodiment of the present disclosure includes the display device described above, and may further include modules or devices having additional functions in addition to the display device.

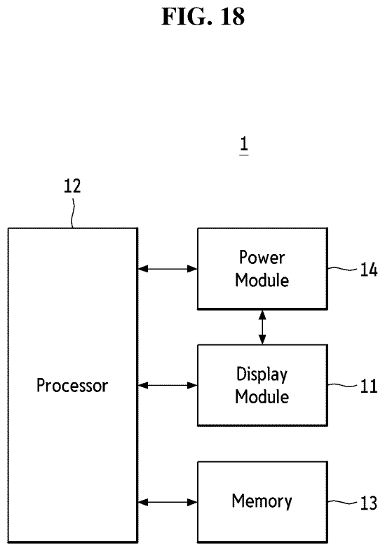

FIG. 18 is a block diagram of an electronic device according to one embodiment of the present disclosure.

Referring to FIG. 18, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for the operation of the processor 12 or the display module 11. When the processor 12 executes an application stored in the memory 15, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

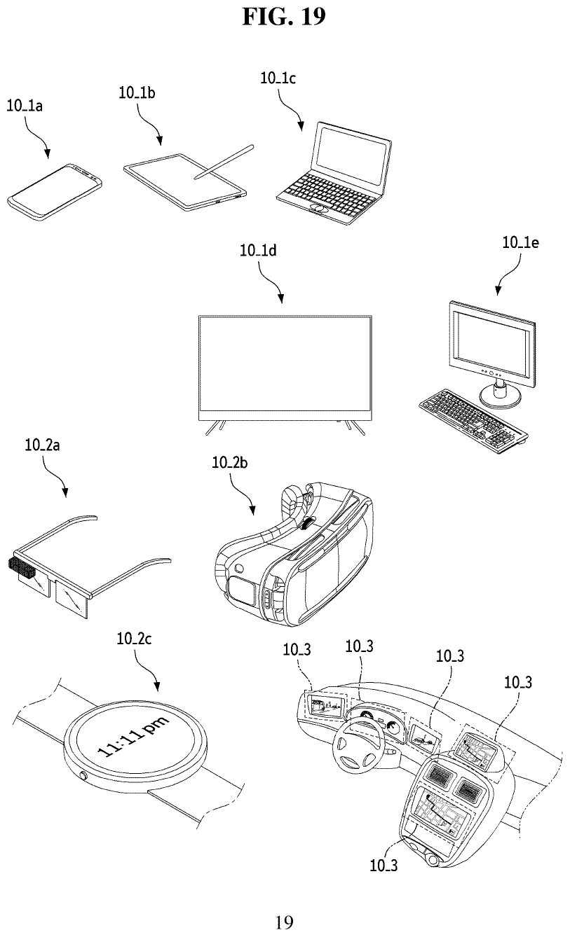

FIG. 19 is a schematic diagram of an electronic device according to various embodiments of the present disclosure.

Referring to FIG. 19, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

In concluding the detailed description, those skilled in the art will appreciate that many variations and modifications can be made to the preferred embodiments without substantially departing from the principles of the present inventive concept. Therefore, the disclosed preferred embodiments of the inventive concept are used in a generic and descriptive sense only and not for purposes of limitation.

What is claimed is:

1. A fingerprint sensor comprising:
a reset voltage line disposed in a first source metal layer on a substrate;
a voltage connection electrode disposed in a second source metal layer on the first source metal layer and connected to the reset voltage line;
a via layer disposed on the second source metal layer and including a via contact hole which exposes a portion of the second source metal layer;
a light-receiving element including a sensor electrode which is disposed on the via layer and connected to the voltage connection electrode and a common electrode which is disposed on the sensor electrode and in the via contact hole; and
a cathode connection electrode disposed in the second source metal layer and having a side directly contacting a side of the common electrode in the via contact hole.

2. The fingerprint sensor of claim 1, wherein the cathode connection electrode includes a first layer which is disposed on the first source metal layer and electrically connected to a first electrode of the second sensor transistor, a second layer which is disposed on the first layer, and a third layer which is disposed on the second layer.

1. The fingerprint sensor of claim 2, wherein a side of the second layer of the cathode connection electrode is inwardly recessed from sides of the first and third layers of the cathode connection electrode and directly contact the side of the common electrode.

4. The fingerprint sensor of claim 2, wherein:
the third layer of the cathode connection electrode includes a tip protruding from a side of the second layer of the cathode connection electrode, and
the common electrode is disconnected around the tip of the third layer of the cathode connection electrode.

5. The fingerprint sensor of claim 1, further comprising:
a low-potential line disposed in the first source metal layer and supplying a low-potential voltage;
a read-out line supplying a sensing signal;
a first sensor transistor controlling a sensing current based on a voltage of the cathode connection electrode;
a second sensor transistor electrically connecting the cathode connection electrode and the low-potential line based on a reset signal; and
a third sensor transistor electrically connecting the read-out line and the first sensor transistor.

6. The fingerprint sensor of claim 5, wherein:
a semiconductor region of the first sensor transistor is disposed in a first active layer on the substrate and includes a silicon (Si)-based material, and
a semiconductor region of the second sensor transistor is disposed in a second active layer on the first active layer and includes an oxide-based material.

7. A fingerprint sensor comprising:
a first sensor transistor including a semiconductor region disposed in a first active layer on a substrate;
a second sensor transistor including a semiconductor region disposed in a second active layer on the first active layer;
a reset voltage line disposed in a first source metal layer on the second active layer and connected to a first electrode of the second sensor transistor;
a sensor node electrode disposed in a second source metal layer on the first source metal layer and electrically connected to a second electrode of the second sensor transistor;
a via layer disposed on the second source metal layer and including a via contact hole which exposes a portion of the second source metal layer;
a light-receiving element disposed on the via layer and including a sensor electrode which is connected to the sensor node electrode and a common electrode which is disposed on the sensor electrode and in the via contact hole; and
a cathode connection electrode disposed in the second source metal layer and having a side directly contact a side of the common electrode in the via contact hole.

8. The fingerprint sensor of claim 7, wherein the cathode connection electrode includes a first layer which is disposed on the first source metal layer and electrically connected to a first electrode of the second sensor transistor, a second layer which is disposed on the first layer, and a third layer which is disposed on the second layer.

9. The fingerprint sensor of claim 8, wherein a side of the second layer of the cathode connection electrode is inwardly recessed from sides of the first and third layers of the cathode connection electrode and directly contact the side of the common electrode.

10. The fingerprint sensor of claim 8, wherein:
the third layer of the cathode connection electrode includes a tip protruding from a side of the second layer of the cathode connection electrode, and
the common electrode is disconnected around the tip of the third layer of the cathode connection electrode.

11. The fingerprint sensor of claim 7, further comprising:
a low-potential line disposed in the first source metal layer and supplying a low-potential voltage; and
a connection electrode disposed in the first source metal layer and electrically connecting a second electrode of the second sensor transistor and the sensor node electrode.

12. The fingerprint sensor of claim 7, further comprising:
a read-out line supplying a sensing signal; and
a third sensor transistor electrically connecting the read-out line and the first sensor transistor.

13. A display device comprising:
a reset voltage line disposed in a first source metal layer on a substrate;
a voltage connection electrode disposed in a second source metal layer on the first source metal layer and connected to the reset voltage line;
a via layer disposed on the second source metal layer and including a via contact hole which exposes a portion of the second source metal layer;
a pixel-defining film disposed on the via layer and defining an emission area and a sensor area;
a light-emitting element including a pixel electrode disposed in the emission area on the via layer, a light-emitting layer disposed on the pixel electrode, and a common electrode disposed on the light-emitting layer;
a light-receiving element including a sensor electrode which is disposed in the sensor area on the via layer and is connected to the voltage connection electrode, a light-receiving layer which is disposed on the sensor electrode, and a common electrode which is disposed on the light-receiving layer;
a separation portion disposed on the pixel-defining film and separating the common electrode of the light-emitting element and the common electrode of the light-receiving element; and
a cathode connection electrode disposed in the second source metal layer and having a side directly contacting a side of the common electrode of the light-receiving element in the via contact hole.

14. The display device of claim 13, wherein the separation portion has a closed-loop shape surrounding the sensor area, the via contact hole, and the cathode connection electrode.

15. The display device of claim 13, further comprising:
a low-potential line disposed in the first source metal layer and supplying a low-potential voltage;
a read-out line supplying a sensing signal;
a first sensor transistor controlling a sensing current based on a voltage of the cathode connection electrode;
a second sensor transistor electrically connecting the cathode connection electrode and the low-potential line in response to a reset signal; and
a third sensor transistor electrically connecting the read-out line and the first sensor transistor.

16. The display device of claim 15, wherein:
the common electrode of the light-emitting element is directly connected to the low-potential line, and
the common electrode of the light-receiving element is electrically connected to the second sensor transistor.

17. The display device of claim 13, further comprising another cathode connection electrode, wherein:
the via layer includes a plurality of via contact holes which are surrounded by the separation portion,
the cathode connection electrode and the another cathode connection electrode are disposed in the respective via contact holes, and
the common electrode of the light-receiving element directly contacts each of the cathode connection electrode and the another cathode connection electrode.

18. The display device of claim 13, wherein the cathode connection electrode includes a first layer which is disposed on the first source metal layer and electrically connected to a first electrode of the second sensor transistor, a second layer which is disposed on the first layer, and a third layer, which is disposed on the second layer.

19. The display device of claim 18, wherein a side of the second layer of the cathode connection electrode is inwardly recessed from sides of the first and third layers of the cathode connection electrode and directly contact the side of the common electrode.

20. The display device of claim 18, wherein:
the third layer of the cathode connection electrode includes a tip protruding from a side of the second layer of the cathode connection electrode, and
the common electrode is disconnected around the tip of the third layer of the cathode connection electrode.

21. An electronic device, comprising:
a display device configured to provide an image;
a processor configured to provide an image data signal to the display device;
a memory configured to store a data information for operation; and
a power module configured to generate power,
wherein the display device comprises:
a reset voltage line disposed in a first source metal layer on a substrate;
a voltage connection electrode disposed in a second source metal layer on the first source metal layer and connected to the reset voltage line;
a via layer disposed on the second source metal layer and including a via contact hole which exposes a portion of the second source metal layer;
a pixel-defining film disposed on the via layer and defining an emission area and a sensor area;
a light-emitting element including a pixel electrode disposed in the emission area on the via layer, a light-emitting layer disposed on the pixel electrode, and a common electrode disposed on the light-emitting layer;
a light-receiving element including a sensor electrode which is disposed in the sensor area on the via layer and is connected to the voltage connection electrode, a light-receiving layer which is disposed on the sensor electrode, and a common electrode which is disposed on the light-receiving layer;
a separation portion disposed on the pixel-defining film and separating the common electrode of the light-emitting element and the common electrode of the light-receiving element; and
a cathode connection electrode disposed in the second source metal layer and having a side directly contacting a side of the common electrode of the light-receiving element in the via contact hole.
